(19) United States
(12) Patent Application Publication
(10) Pub. No.: US 2026/0324242 A1
(43) Pub. Date: Oct. 15, 2026

(54) DISPLAY MODULE AND ELECTRONIC DEVICE HAVING THE SAME

(71) Applicant: SAMSUNG DISPLAY CO., LTD., YONGIN-SI (KR)

(72) Inventors: WOOYOUNG KIM, Yongin-si (KR); SU JEONG KIM, Yongin-si (KR); KYEONGJONG KIM, Yongin-si (KR); ISRAEL ESTEBAN LAZO MARTINEZ, Yongin-si (KR); JUNG-WOO LEE, Yongin-si (KR); JINHYEONG LEE, Yongin-si (KR)

(21) Appl. No.: 19/383,844

(22) Filed: Nov. 10, 2025

(30) Foreign Application Priority Data
Apr. 9, 2025 (KR) 10-2025-0046062

(51) Int. Cl. H10K 59/38; H10K 59/122; H10K 59/80

(52) U.S. Cl. CPC H10K 59/38; H10K 59/122; H10K 59/8792

(57) ABSTRACT

A display module includes a light-emitting diode layer, a light-blocking film, a red diffraction reduction part and a red color filter. The light-emitting diode layer includes a plurality of light-emitting diodes. The light-blocking film has a plurality of transmission openings defined therein, the plurality of transmission openings respectively overlapping with the plurality of light-emitting diodes in a plan view, and absorbing incident light. The red diffraction reduction part is disposed in a red transmission opening among the plurality of transmission openings. The red color filter is disposed in the red transmission opening and covers the red diffraction reduction part. In the plan view, a center of mass of the red diffraction reduction part is spaced apart from a center of mass of the red transmission opening.

### CROSS-REFERENCE TO RELATED APPLICATIONS

This application claims priority under 35 U.S.C. §119 to Korean Patent Application No. 10-2025-0046062, filed on Apr. 9, 2025 in the Korean Intellectual Property Office, the disclosure of which is incorporated by reference in its entirety herein.

### TECHNICAL FIELD

The present disclosure relates to a display module and an electronic device including the same. More particularly, the present disclosure relates to a display module including a plurality of diffraction reduction parts to reduce diffraction patterns visible to a user, and an electronic device including the same.

### DISCUSSION OF RELATED ART

A display panel may include a plurality of pixels configured to emit light of displaying visual information to a user. In a case in which the plurality of pixels having a same shape as each other are arranged at constant intervals, a diffraction grating may be formed due to the plurality of pixels. Due to the formation of the diffraction grating, a diffraction pattern may be visible in light emitted from the display panel. In addition, due to the formation of the diffraction grating, a diffraction pattern may be visible in light reflected by the display panel. The diffraction grating and the diffraction pattern may lead to a decrease in display quality.

### SUMMARY

The present disclosure is to resolve the above problems and relates to a display module including a plurality of diffraction reduction parts, and an electronic device including the same.

A display module according to an embodiment of the present disclosure may include a base member, a light-emitting diode layer, an encapsulation layer, a light-blocking film, a red diffraction reduction part, and a red color filter. The light-emitting diode layer may be disposed on the base member and include a plurality of light-emitting diodes. The encapsulation layer may be disposed on the light-emitting diode layer and cover the plurality of light-emitting diodes. The light-blocking film may be disposed on the encapsulation layer, have a plurality of transmission openings defined therein, the plurality of transmission openings respectively overlapping with the plurality of light-emitting diodes in a plan view, and absorbing incident light. The red diffraction reduction part may be disposed in a red transmission opening among the plurality of transmission openings. The red color filter may be disposed in the red transmission opening and cover the red diffraction reduction part. In the plan view, a center of mass of the red diffraction reduction part may be spaced apart from a center of mass of the red transmission opening.

In an embodiment of the present disclosure, the light-emitting diode layer may further include a pixel definition film. The pixel definition film may have a plurality of light-emission openings defined therein, each of the plurality of light-emission openings overlapping with a corresponding transmission opening among the plurality of transmission openings in the plan view, overlap with the light-blocking film and absorbing incident light.

In an embodiment of the present disclosure, the light-blocking film may include a same material as the red diffraction reduction part.

In an embodiment of the present disclosure, a green diffraction reduction part and a green color filter may be further included. The green diffraction reduction part may be disposed in a green transmission opening among the plurality of transmission openings. The green color filter may be disposed in the green transmission opening and cover the green diffraction reduction part. The plurality of light-emitting diodes may include a red light-emitting diode and a green light-emitting diode. The red light-emitting diode may emit light having a first wavelength and overlap with the red transmission opening in the plan view. The green light-emitting diode may emit light having a second wavelength different from the first wavelength and overlap with the green transmission opening in the plan view. The red color filter may allow transmission of light having the first wavelength and absorb light having the second wavelength. The green color filter may allow transmission of light having the second wavelength and absorb light having the first wavelength. In the plan view, a center of mass of the red diffraction reduction part may be spaced apart from a center of mass of the red transmission opening by a red-part spacing distance in a red-part spacing direction. In the plan view, a center of mass of the green diffraction reduction part may be spaced apart from a center of mass of the green transmission opening by a green-part spacing distance different from the red-part spacing distance in a green-part spacing direction different from the red-part spacing direction.

In an embodiment of the present disclosure, a blue diffraction reduction part and a blue color filter may be further included. The blue diffraction reduction part may be disposed in a blue transmission opening among the plurality of transmission openings. The blue color filter may be disposed in the blue transmission opening and cover the blue diffraction reduction part. The plurality of light-emitting diodes may further include a blue light-emitting diode. The blue light-emitting diode may emit light having a third wavelength and overlap with the blue transmission opening in the plan view. The blue color filter may allow transmission of light having the third wavelength and absorb light having the first wavelength and light having the second wavelength. In the plan view, a center of mass of the blue diffraction reduction part may be spaced apart from a center of mass of the blue transmission opening by a blue-part spacing distance different from the red-part spacing distance and the green-part spacing distance in a blue-part spacing direction different from the red-part spacing direction and the green-part spacing direction.

In an embodiment of the present disclosure, the first wavelength may be in a range of about 600 nm to about 750 nm. The second wavelength may be in a range of about 500 nm to about 590 nm. The third wavelength may be in a range of about 450 nm to about 490 nm. In the plan view, a value obtained by dividing an area of the red diffraction reduction part by an area of the red transmission opening may be defined as a red-part area ratio. In the plan view, a value obtained by dividing an area of the green diffraction reduction part by an area of the green transmission opening may be defined as a green-part area ratio. In the plan view, a value obtained by dividing an area of the blue diffraction reduction part by an area of the blue transmission opening may be defined as a blue-part area ratio. The blue-part area ratio may be less than the red-part area ratio and the green-part area ratio.

In an embodiment of the present disclosure, the green-part area ratio and the red-part area ratio may be substantially same.

In an embodiment of the present disclosure, the first wavelength may be in a range of about 600 nm to about 750 nm. The second wavelength may be in a range of about 500 nm to about 590 nm. The third wavelength may be in a range of about 450 nm to about 490 nm. In the plan view, a value obtained by dividing an area of the red diffraction reduction part by an area of the red transmission opening may be defined as a red-part area ratio. In the plan view, a value obtained by dividing an area of the green diffraction reduction part by an area of the green transmission opening may be defined as a green-part area ratio. In the plan view, a value obtained by dividing an area of the blue diffraction reduction part by an area of the blue transmission opening may be defined as a blue-part area ratio. The red-part area ratio, the green-part area ratio, and the blue-part area ratio may be in a range of about 0.05 to about 0.20.

In an embodiment of the present disclosure, an input sensor unit may be further included. The input sensor unit may be disposed between the encapsulation layer and the light-blocking film and detecting an input applied from outside. The input sensor unit may include a lower sensor electrode disposed on the encapsulation layer, an intermediate input sensor insulating layer disposed on the lower sensor electrode, and an upper sensor electrode disposed on the intermediate input sensor insulating layer.

In an embodiment of the present disclosure, a light reflection unit may be further included. The light reflection unit may overlap with the red diffraction reduction part and reflect incident light. The input sensor unit may further include an upper input sensor insulating layer covering the upper input sensor electrode. The light reflection unit may be disposed between the encapsulation layer and the upper input sensor insulating layer.

A display module according to an embodiment of the present disclosure may include a base member, a light-emitting diode layer, an encapsulation layer, a light-blocking film, a first diffraction reduction part and a first color filter. The light-emitting diode layer may be disposed on the base member and include a plurality of light-emitting diodes. The encapsulation layer may be disposed on the light-emitting diode layer and cover the plurality of light-emitting diodes. The light-blocking film may be disposed on the encapsulation layer, have a plurality of transmission openings defined therein, the plurality of transmission openings respectively overlapping with a corresponding light-emitting diode among the plurality of light-emitting diodes in a plan view, and absorbing incident light. The first diffraction reduction part may be disposed in a first transmission opening among the plurality of transmission openings. The first color filter may be disposed in the first transmission opening and cover the first diffraction reduction part. In the plan view, a center of mass of the first diffraction reduction part may not overlap with a center of mass of the first transmission opening.

In an embodiment of the present disclosure, the light-emitting diode layer may further include a pixel definition film. The pixel definition film may have a plurality of light-emission openings defined therein, each of the plurality of light-emission openings overlapping in the plan view with a corresponding transmission opening among the plurality of transmission openings, overlap with the light-blocking film and absorbing incident light.

In an embodiment of the present disclosure, a second diffraction reduction part may be further included. The second diffraction reduction part may be disposed in a second transmission opening among the plurality of transmission openings. In the plan view, a center of mass of the second transmission opening may be spaced apart from a center of mass of the first transmission opening by a first arrangement distance in a first arrangement direction. A center of mass of the second diffraction reduction part may be spaced apart from a center of mass of the first diffraction reduction part by a distance different from the first arrangement distance in a direction different from the first arrangement direction.

In an embodiment of the present disclosure, a third diffraction reduction part may be further included. The third diffraction reduction part may be disposed in a third transmission opening among the plurality of transmission openings. In the plan view, a center of mass of the third transmission opening may be spaced apart from the center of mass of the first transmission opening by a second arrangement distance in a second arrangement direction intersecting with the first arrangement direction. A center of mass of the third diffraction reduction part may be spaced apart from the center of mass of the first diffraction reduction part by a distance different from the second arrangement distance in a direction different from the second arrangement direction.

In an embodiment of the present disclosure, a second diffraction reduction part and a third diffraction reduction part may be further included. The second diffraction reduction part may be disposed in a second transmission opening among the plurality of transmission openings. The third diffraction reduction part may be disposed in a third transmission opening among the plurality of transmission openings. In the plan view, a center of mass of the second transmission opening may be spaced apart from a center of mass of the first transmission opening by a first arrangement distance in a first arrangement direction. A center of mass of the second diffraction reduction part may be spaced apart from the center of mass of the first diffraction reduction part by the first arrangement distance in the first arrangement direction. In the plan view, a center of mass of the third transmission opening may be spaced apart from the center of mass of the second transmission opening by the first arrangement distance in the first arrangement direction. A center of mass of the third diffraction reduction part may be spaced apart from the center of mass of the second diffraction reduction part by a distance different from the first arrangement distance in a direction different from the first arrangement direction.

In an embodiment of the present disclosure, a fourth diffraction reduction part may be further included. The fourth diffraction reduction part may be disposed in a fourth transmission opening among the plurality of transmission openings. In the plan view, a center of mass of the fourth transmission opening may be spaced apart from the center of mass of the third transmission opening by a first arrangement distance in a first arrangement direction. A center of mass of the fourth diffraction reduction part may be spaced apart from the center of mass of the third diffraction reduction part by the first arrangement distance in the first arrangement direction.

In an embodiment of the present disclosure, a second diffraction reduction part and a third diffraction reduction part may be further included. The second diffraction reduction part may be disposed in a second transmission opening among the plurality of transmission openings. The third diffraction reduction part may be disposed in a third transmission opening among the plurality of transmission openings. In the plan view, a center of mass of the second transmission opening may be spaced apart from a center of mass of the first transmission opening in a first arrangement direction. A center of mass of the second diffraction reduction part may be spaced apart from a center of mass of the first diffraction reduction part in the first arrangement direction. In the plan view, a center of mass of the third transmission opening may overlap with a straight line connecting the center of mass of the first transmission opening and the center of mass of the second transmission opening. In the plan view, a center of mass of the third diffraction reduction part may not overlap with a straight line connecting the center of mass of the first diffraction reduction part and the center of mass of the second diffraction reduction part.

In an embodiment of the present disclosure, a fourth diffraction reduction part may be further included. The fourth diffraction reduction part may be disposed in a fourth transmission opening among the plurality of transmission openings. The fourth transmission opening may be disposed between the first transmission opening and the second transmission opening. In the plan view, a center of mass of the fourth transmission opening may overlap with the straight line connecting the center of mass of the first transmission opening and the center of mass of the second transmission opening. In the plan view, a center of mass of the fourth diffraction reduction part may overlap with the straight line connecting the center of mass of the first diffraction reduction part and the center of mass of the second diffraction reduction part.

In an embodiment of the present disclosure, the fourth transmission opening includes a plurality of fourth transmission openings and the fourth diffraction reduction part may include a plurality of fourth diffraction reduction parts. The plurality of fourth diffraction reduction parts may each be disposed in a corresponding fourth transmission opening among the plurality of fourth transmission openings.

An electronic device according to an embodiment of the present disclosure may include a base member, a light-emitting diode layer, a light-blocking film, a red diffraction reduction part, a green diffraction reduction part, a red color filter and a green color filter. The light-emitting diode layer may be disposed on the base member and include a red light-emitting diode emitting light having a first wavelength and a green light-emitting diode emitting light having a second wavelength different from the first wavelength. The light-blocking film may be disposed on the light-emitting diode layer, have a red transmission opening overlapping with the red light-emitting diode in a plan view and a green transmission opening overlapping with the green light-emitting diode in the plan view, and absorbing incident light. The red diffraction reduction part may be disposed in the red transmission opening. The green diffraction reduction part may be disposed in the green transmission opening. The red color filter may be disposed in the red transmission opening, cover the red diffraction reduction part, and allowing transmission of light having the first wavelength and absorb light having the second wavelength. The green color filter may be disposed in the green transmission opening, cover the green diffraction reduction part, and allow transmission of light having the second wavelength and absorb light having the first wavelength. In the plan view, a center of mass of the red diffraction reduction part may be spaced apart from a center of mass of the red transmission opening by a red-part spacing distance in a red-part spacing direction. A center of mass of the green diffraction reduction part may be spaced apart from a center of mass of the green transmission opening by a green-part spacing distance different from the red-part spacing distance in a green-part spacing direction different from the red-part spacing direction.

According to an embodiment of the present disclosure, the present disclosure may provide a display module including a plurality of diffraction reduction parts to reduce visibility of a diffraction pattern to a user, and an electronic device including the same.

### BRIEF DESCRIPTION OF THE DRAWINGS

These and/or other features will become apparent and more readily appreciated from the following description of embodiments, taken in conjunction with the accompanying drawings in which:

FIG. 1 is an illustration of a display device according to an embodiment of the present disclosure;

FIG. 2 is an illustration of a cross-sectional view of a display device according to an embodiment of the present disclosure;

FIG. 3 is a plan view of a display panel according to an embodiment of the present disclosure;

FIG. 4 is an equivalent circuit diagram of a pixel according to an embodiment of the present disclosure;

FIG. 5 is an illustration of a light-emission control signal and scan signals applied to the pixel shown in FIG. 4;

FIG. 6 is a cross-sectional view of a display module according to an embodiment of the present disclosure;

FIG. 7 is a more detailed illustration of some configurations in a magnified view of the AA section shown in FIG. 6;

FIG. 8 is a plan view of any one of the plurality of pixels according to an embodiment of the present disclosure;

FIG. 9A is an illustration of a plan view of a display module according to an embodiment of the present disclosure;

FIG. 9B is a magnified view of the BB section shown in FIG. 9A;

FIGS. 10 and 11 are cross-sectional views of a display module according to an embodiment of the present disclosure;

FIGS. 12, 13 and 14 are plan views of any one of the plurality of pixels PX-1 according to an embodiment of the present disclosure;

FIG. 15A is a plan view of a display module according to an embodiment of the present disclosure;

FIG. 15B is a magnified view of the BB-1 section shown in FIG. 15A;

FIG. 16A is a plan view of a display module according to an embodiment of the present disclosure;

FIG. 16B is a magnified view of the BB-2 section shown in FIG. 16A;

FIG. 17A is a plan view of a display module according to an embodiment of the present disclosure;

FIG. 17B is a magnified view of the BB-3 section shown in FIG. 17A;

FIG. 18 is a block diagram of an electronic device according to an embodiment of the present disclosure; and

FIG. 19 are schematic diagrams of electronic devices according to various embodiments of the present disclosure.

### DETAILED DESCRIPTION OF EMBODIMENTS

References will now be made in detail to certain embodiments, of which examples are illustrated in the accompanying drawings, where like reference numerals refer to like elements throughout. The described embodiments may have a variety of forms and permutations and embodiments of the present disclosure shall by no means be construed as being limited to the described embodiments. Rather, embodiments of the present disclosure shall be construed to encompass all forms, permutations, equivalents and substitutes covered by the technical ideas and scope of the present disclosure. Accordingly, embodiments are merely described below, by referring to the figures, to explain features of embodiments of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not necessarily be restricted to the thicknesses, ratios, dimensions, etc. illustrated in the drawings.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

A display device according to an embodiment may be applicable to various electronic devices. An electronic device according to an embodiment may include the described display device and further include a module or a device having an additional function in addition to the display device.

A term, such as “overlapping,” refers to disposition on a normal direction of a surface of a component without being limited to disposition on or below the surface.

A display device may include diffraction reduction parts disposed in transmission openings of a light-blocking film to reduce a diffraction phenomenon, such as the generation of a diffraction pattern when the transmission openings are disposed along a pattern. A center of mass of each of the plurality of diffraction reduction parts may be spaced apart from the center of mass of the transmission opening in a plan view. Diffraction reduction parts of adjacent pixels may be irregularly disposed by being shifted in a different distance and in a different arrangement direction so that the generation of a diffraction pattern may be further reduced.

FIG. 1 is an illustration of a display device DD according to an embodiment of the present disclosure.

Referring to FIG. 1, a display area DA and a non-display area NDA may be defined in the display device DD. The display device DD may be a smartphone.

Directions pointed by the first through the third directional axes DR1, DR2 and DR3 are merely a relative concept and may be converted into other directions. Hereinafter, a first through a third directions DR1, DR2 and DR3 are directions pointed by the first through the third directional axes DR1, DR2 and DR3, respectively, and described with the same figure references. For example, while in some embodiments the first to third directional axes DR1, DR2 and DR3 may be perpendicular to each other, embodiments of the present disclosure are not necessarily limited thereto and the first to third directional axes DR1, DR2 and DR3 may intersect each other at various different angles.

The display area DA may be an area that displays an image in the display device DD. Light may be emitted from the display area DA. Light emitted from a plurality of light-emitting diodes may be emitted from the display area DA to show an image on the display area DA.

The non-display area NDA may be an area that does not display an image in the display device DD and does not include a plurality of light-emitting diodes. Light may not be emitted from the non-display area NDA. In an embodiment, the non-display area NDA may surround the display area DA (e.g., at least partially surround in a plan view).

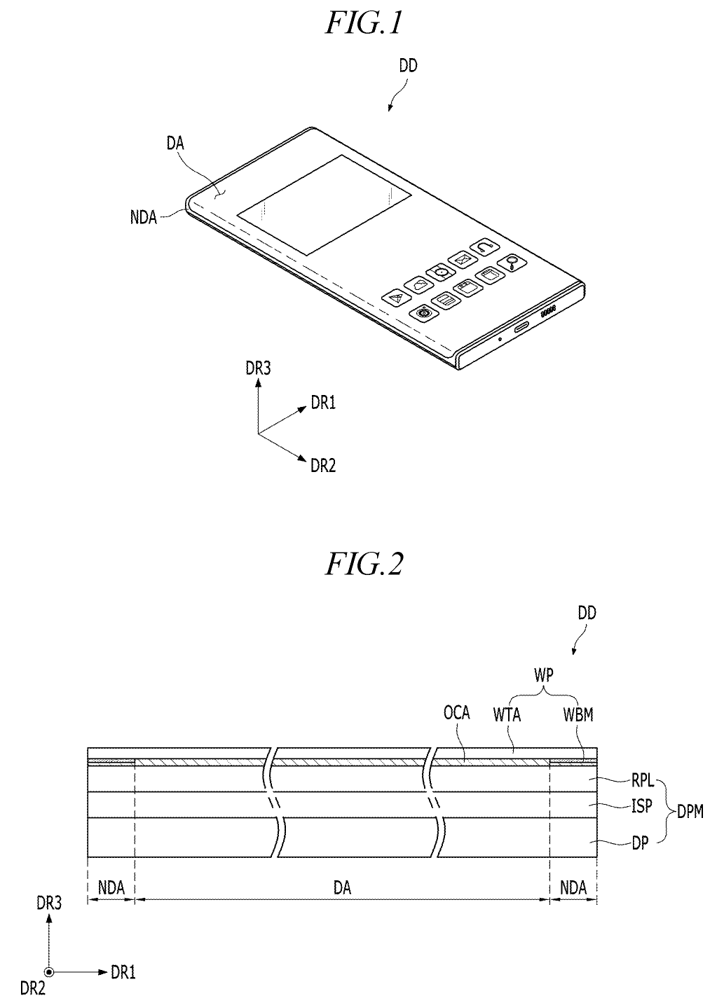

FIG. 2 is a cross-sectional view of a display device DD according to an embodiment of the present disclosure.

Referring to FIG. 2, the display device DD may include a display module DPM, a window member WP, and an adhesive part OCA. In FIG. 2, a lamination structure of the display device DD is simply illustrated for economy of explanation.

The display module DPM may include a display panel DP, an input sensor unit ISP, and a reflection protection layer RPL. The display module DPM may be configured to emit light on the window member WP.

Light may be emitted from the display panel DP. The display panel DP may be a light-emitting display panel. In an embodiment, the display panel DP may be an organic light-emitting display panel, a quantum dot light-emitting display panel or a micro light-emitting display panel. The display panel DP may include a plurality of light-emitting diodes.

The input sensor unit ISP may be disposed on the display panel DP (e.g., disposed directly thereon in the third direction DR3). The input sensor unit ISP may be configured to obtain coordination information of an external input. In an embodiment, at least one of a capacitance type input sensor, a resistance film type input sensor, an optical sensor, an electromagnetic resonance type input sensor, an ultrasonic type input sensor and an infrared wave type input sensor may be used as the input sensor unit ISP.

The reflection protection layer RPL may be disposed on the input sensor unit ISP (e.g., disposed directly thereon in the third direction DR3). The reflection protection layer RPL may be configured to reduce light reflectivity of external light incident from an upper side of the window member WP. A reflection protection layer RPL may include a color filter layer.

The reflection protection layer RPL may not include a polarizing film. Therefore, the reflection protection layer RPL may allow transmission of at least some of light orthogonal to each other. In addition, the reflection protection layer RPL may allow transmission of at least some of light oscillating in a direction parallel to a plane defined by a first direction DR1 and a second direction DR2.

For example, the reflection protection layer RPL may allow transmission of at least some of light oscillating in the first direction DR1 and at least some of light oscillating in the second direction DR2. Light transmittance of light transmitting through the reflection protection layer RPL and oscillating in the first direction DR1 and light transmittance of light transmitting through the reflection protection layer RPL and oscillating in the second direction DR2 may be substantially the same as each other.

The window member WP may be disposed on the reflection protection layer RPL (e.g., disposed directly thereon in the third direction DR3). The window member WP may include a light transmitting part WTA and a light-blocking part WBM.

The light transmitting part WTA may overlap with the display area DA. The light transmitting part WTA may include glass and/or a synthetic resin. The light transmitting part WTA is not necessarily limited to a single layer. The light transmitting part WTA may include two or more films attached by an adhesive member. The light transmitting part WTA may allow transmission of light emitted from the display panel DP.

The light-blocking part WBM may overlap with the non-display area NDA. The light-blocking part WBM may partially overlap with the light transmitting part WTA. The light-blocking part WBM may be disposed below the light transmitting part WTA. The light-blocking part WBM may be configured to block light emitted from the display panel DP.

The adhesive part OCA may be disposed between the display module DPM and the window member WP (e.g., in the third direction DR3). The display module DPM and the window member WP may be attached by the adhesive part OCA.

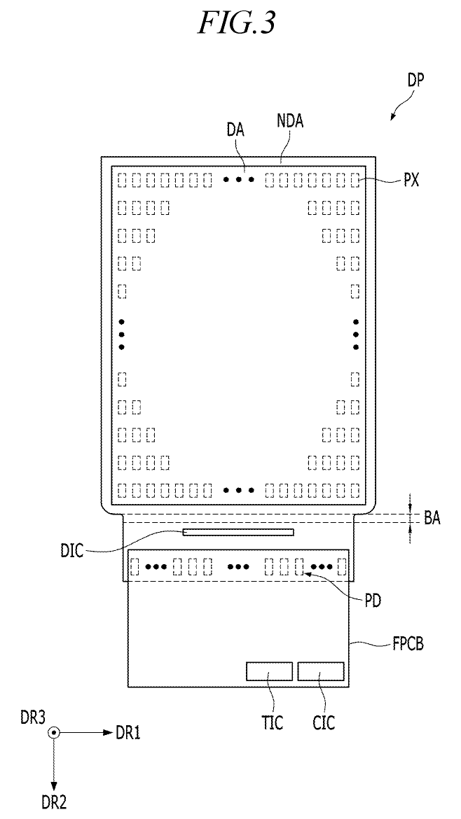

FIG. 3 is a plan view of a display panel DP according to an embodiment of the present disclosure.

Referring to FIG. 3, the display panel DP may have a display area DA and a non-display area NDA defined therein. The non-display area NDA may be defined along the surrounding of the display area DA (e.g., in a plan view). The display area DA may correspond to the display area DA of the display device DD shown in FIG. 1. The non-display area NDA may correspond to the non-display area NDA of the display device DD shown in FIG. 1.

In an embodiment, the display panel DP may include a plurality of pixels PX, a data integrated circuit DIC, a plurality of pads PD, a flexible printed circuit board FPCB, an input sensor integrated circuit TIC, and a control integrated circuit CIC.

The data integrated circuit DIC may be electrically connected to the pixels PX of the display region DA and configured to provide data signal to the pixels PX.

The input sensor integrated circuit TIC and the control integrated circuit CIC may be mounted in the flexible printed circuit board FPCB and configured to receive electronic signal from the plurality of pads PD.

The input sensor integrated circuit TIC may use the plurality of pads PD to process a signal corresponding to a change of current applied to the display area DA due to a user’s touch or a signal corresponding to an applied external pressure via the input sensor unit ISP.

The control integrated circuit CIC may be a circuit configured to control at least one of the data integrated circuit DIC and the input sensor integrated circuit TIC.

A bendable area BA of the display panel DP may be bent.

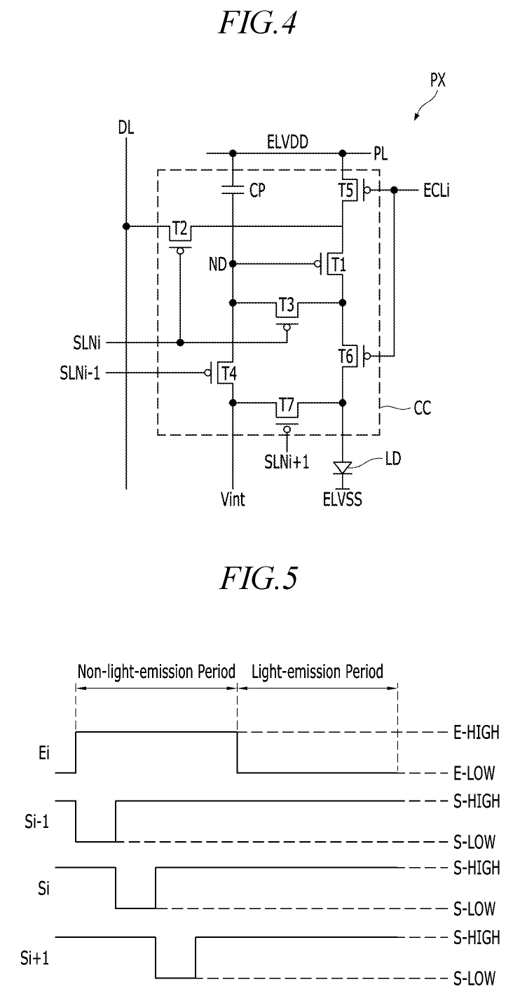

FIG. 4 is an equivalent circuit of a pixel PX according to an embodiment of the present disclosure. FIG. 5 is an illustration of light-emission control signals Ei and scan signals Si-1, Si and Si+1 applied to the pixel PX shown in FIG. 4. FIG. 4 illustrates the pixel PX connected to an i-th scan line SLi and an i-th light-emitting control line ECLi.

The pixel PX may include an organic light-emitting diode OLED and a pixel circuit CC. In an embodiment, the pixel circuit CC may include a plurality of transistors T1 through T7 and a capacitor CP. The pixel circuit CC may be configured to control an amount of current flowing through the organic light-emitting diode OLED in response to a data signal.

The organic light-emitting diode OLED may be configured to emit light with a selectable luminance corresponding to the amount of current provided from the pixel circuit CC. In an embodiment, a level of a first power ELVDD may be set higher than a level of a second power ELVSS.

The plurality of transistors T1 to T7 may each include an input electrode (e.g., a source electrode), an output electrode (e.g., a drain electrode), and a control electrode (e.g., a gate electrode). In the present disclosure, for convenience, one of the input electrode and the output electrode may be referred to as a first electrode, and the other may be referred to as a second electrode.

The first electrode of the first transistor T1 is connected to the first power ELVDD via the fifth transistor T5, and the second electrode is connected to an anode electrode of the organic light-emitting diode OLED via the sixth transistor T6. The first transistor T1 may be referred to as a driving transistor in this specification.

The first transistor T1 is configured to control an amount of current flowing through the organic light-emitting diode OLED in response to a voltage applied to the control electrode.

The second transistor T2 is connected between the data line DL and the first electrode of the first transistor T1. In addition, the control electrode of the second transistor T2 is connected to the i-th scan line SLNi. In case that the i-th scan signal Si is provided to the i-th scan line SLNi, the second transistor T2 is turned on to electrically connect the data line DL and the first electrode of the first transistor T1.

The third transistor T3 is connected between the second electrode of the first transistor T1 and the control electrode. The control electrode of the third transistor T3 is connected to the i-th scan line SLNi. In case that the i-th scan signal Si is provided to the i-th scan line SLNi, the third transistor T3 is turned on to electrically connect the second electrode of the first transistor T1 and the control electrode. Accordingly, in case that the third transistor T3 is turned on, the first transistor T1 is connected in a form of a diode.

The fourth transistor T4 is connected between a node ND and an initialization power generation unit. In addition, the control electrode of the fourth transistor T4 is connected to the (i-1)-th scan line SLNi-1. When the (i-1)-th scan signal Si-1 is provided to the (i-1)-th scan line SLNi-1, the fourth transistor T4 is turned on to provide an initialization voltage Vint to the node ND.

The fifth transistor T5 is connected between a power line PL and the first electrode of the first transistor T1. The control electrode of the fifth transistor T5 is connected to the i-th light-emission control line ECLi.

The sixth transistor T6 is connected between the second electrode of the first transistor T1 and the anode electrode of the organic light-emitting diode OLED. In addition, the control electrode of the sixth transistor T6 is connected to the i-th light-emission control line ECLi.

The seventh transistor T7 is connected between the initialization power generation unit and the anode electrode of the organic light-emitting diode OLED. In addition, the control electrode of the seventh transistor T7 is connected to the (i+1)-th scan line SLNi+1. In case that the (i+1)-th scan signal Si+1 is provided to the (i+1)-th scan line SLNi+1, such seventh transistor T7 is turned on to provide the initialization voltage Vint to the anode electrode of the organic light-emitting diode OLED.

The seventh transistor T7 may increase black expression capability of the pixel PX. Particularly, in case that the seventh transistor T7 is turned on, a parasitic capacitor of the organic light-emitting diode OLED is discharged. Then, in case that black luminance is implemented, the organic light-emitting diode OLED does not emit light due to the leakage current from the first transistor T1, and accordingly, the black expression capability may be increased.

Additionally, in FIG. 4, the control electrode of the seventh transistor T7 is shown to be connected to the (i+1)-th scan line SLNi+1, but embodiments of the present disclosure are not necessarily limited to this configuration. In an embodiment of the present disclosure, the control electrode of the seventh transistor T7 may be connected to the i-th scan line SLi or the (i-1)-th scan line SLi-1.

Illustration of FIG. 4 is based on PMOS, but embodiments of the present disclosure are not necessarily limited to this configuration. In an embodiment of the present disclosure, the pixel PX may be composed of NMOS. In an embodiment of the present disclosure, the pixel PX may be composed of a combination of NMOS and PMOS.

The capacitor CP is disposed between the power line PL and the node ND. The capacitor CP is configured to store a voltage corresponding to the data signal. In case that the fifth transistor T5 and the sixth transistor T6 are turned on, the amount of current flowing through the first transistor T1 may be determined according to the voltage stored in the capacitor CP.

In the present disclosure, a structure of the pixel PX is not necessarily limited to what is illustrated in FIG. 4. In an embodiment of the present disclosure, the pixel PX may be implemented in various forms configured for the organic light-emitting diode OLED to emit light.

Referring to FIG. 5, the light emission control signal Ei may have a high level E-HIGH or a low level E-LOW. The scan signals SLi-1, SLi, and SLi+1 may each have a high level S-HIGH or a low level S-LOW.

In case that the light emission control signal Ei has a high level E-HIGH, the fifth transistor T5 and the sixth transistor T6 are turned off. In case that the fifth transistor T5 is turned off, the power line PL and the first electrode of the first transistor T1 are electrically cut off. In case that the sixth transistor T6 is turned off, the second electrode of the first transistor T1 and the anode electrode of the organic light-emitting diode OLED are electrically cut off. Accordingly, the organic light-emitting diode OLED does not emit light while the light emission control signal Ei having a high level E-HIGH is provided to the i-th light emission control line ECLi.

Thereafter, in case that the (i-1)-th scan signal Si-1 to be provided to the (i-1)-th scan line SLi-1 has a low level S-LOW, the fourth transistor T4 is turned on. In case that the fourth transistor T4 is turned on, the initialization voltage Vint is provided to the node ND.

In case that the i-th scan signal Si provided to the i-th scan line SLi has a low level S-LOW, the second transistor T2 and the third transistor T3 are turned on.

In case that the second transistor T2 is turned on, a data signal is provided to the first electrode of the first transistor T1. Here, since the node ND is initialized to the initialization voltage Vint, the first transistor T1 is turned on. In case that the first transistor T1 is turned on, a voltage corresponding to the data signal is provided to the node ND. Here, the capacitor CP stores a voltage corresponding to the data signal.

In case that the (i+1)-th scan signal Si+1 to be provided to the (i+1)-th scan line SLi+1 has a low level S-LOW, the seventh transistor T7 is turned on.

In case that the seventh transistor T7 is turned on, the initialization voltage Vint is provided to the anode electrode of the organic light-emitting diode OLED, thereby discharging the parasitic capacitor of the organic light-emitting diode OLED.

In case that the light emission control signal Ei to be provided to the light emission control line ECLi has a low level E-LOW, the fifth transistor T5 and the sixth transistor T6 are turned on. In case that the fifth transistor T5 is turned on, the first power ELVDD is provided to the first electrode of the first transistor T1. When the sixth transistor T6 is turned on, the second electrode of the first transistor T1 and the anode electrode of the organic light-emitting diode OLED are electrically connected. Then, the organic light-emitting diode OLED generates light of a predetermined luminance in response to the amount of supplied current.

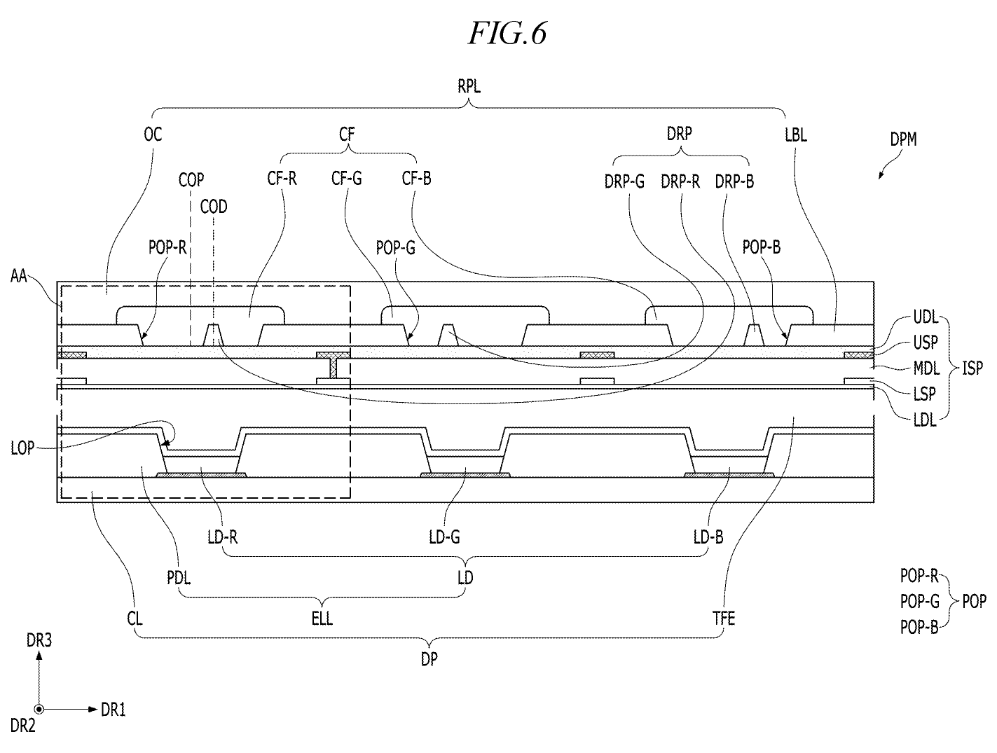

FIG. 6 is a cross-sectional view of a display module DPM according to an embodiment of the present disclosure.

Referring to FIG. 6, in an embodiment the display module DPM may include a display panel DP, an input sensor unit ISP, and a reflection protection layer RPL. The display panel DP may be simply illustrated in FIG. 6.

In an embodiment, the display panel DP may include a circuit layer CL, a light-emitting diode layer ELL, and an encapsulation layer TFE. Light may be emitted from the display panel DP.

The circuit layer CL may be configured to transfer electric signal. The electric signal transferred from the circuit layer CL may be transferred to the light-emitting diode layer ELL. A configuration of the circuit layer CL will be described in detail in relation with other figures.

In an embodiment, the light-emitting diode layer ELL may include a pixel definition film PDL and a plurality of light-emitting diodes LD. The light-emitting diode layer ELL may be disposed on the circuit layer CL. The light-emitting diode layer ELL may be configured to receive an electric signal from the circuit layer CL to emit light.

The pixel definition film PDL may be disposed on the circuit layer CL (e.g., disposed directly thereon in the third direction DR3). The pixel definition film PDL may have a plurality of light-emission openings LOP defined therein. Any one of the plurality of light-emitting diodes LD may be disposed in the plurality of light-emission openings LOP respectively. The pixel definition film PDL may be configured to absorb incident light. In an embodiment, the light absorbed by the pixel definition film PDL may be light having wavelength in a visible spectrum.

In an embodiment, the plurality of light-emitting diodes LD may include a red light-emitting diode LD-R, a green light-emitting diode LD-G, and a blue light-emitting diode LD-B. However, embodiments of the present disclosure are not necessarily limited thereto and the number of the plurality of light-emitting diodes LD and the colors of the light emitted thereby may vary. The plurality of light-emitting diodes LD may be disposed on the circuit layer CL.

At least some portion of each of the plurality of light-emitting diodes LD may be disposed in any one of the plurality of light-emission openings LOP. The plurality of light-emitting diodes LD may be configured to emit light.

In an embodiment, the red light-emitting diode LD-R may be disposed in some of the plurality of light-emission openings LOP. The red light-emitting diode LD-R may be configured to emit light having a first wavelength. The first wavelength may be in a range of about 600 nm to about 750 nm. Light having the first wavelength may be red light.

In an embodiment, the green light-emitting diode LD-G may be disposed in some of the plurality of light-emission openings LOP where the red light-emitting diode LD-R is not disposed. The green light-emitting diode LD-G may be configured to emit light having a second wavelength different from the first wavelength. The second wavelength may be in a range of about 500 nm to about 590 nm. Light having the second wavelength may be green light.

In an embodiment, the blue light-emitting diode LD-B may be disposed in some of the plurality of light-emission openings LOP where the red light-emitting diode LD-R and the green light-emitting diode LD-G are not disposed. The blue light-emitting diode LD-B may be configured to emit light having a third wavelength different from the first wavelength and the second wavelength. The third wavelength may be in a range of about 450 nm to about 490 nm. Light having the third wavelength may be blue light.

For example, the plurality of light-emitting diodes LD may be configured to emit light having different wavelengths one another. In other words, the plurality of light-emitting diodes LD may include different types of light-emitting materials one another. In addition, a specific structure of the plurality of light-emitting diodes LD may be different one another. For example, a thickness of the plurality of light-emitting diodes LD (e.g., in the third direction DR3) may be different one another.

However, a layer structure consisting of each of the plurality of light-emitting diodes LD may be identical. For example, the plurality of light-emitting diodes LD may each include an anode electrode, a hole functional layer, a light-emission layer, an electron functional layer and a cathode electrode. A configuration of the plurality of light-emitting diodes LD will be described in detail in relation with other figures.

The encapsulation layer TFE may be disposed on the plurality of light-emitting diodes LD. The encapsulation layer TFE may cover the plurality of light-emitting diodes LD. The encapsulation layer TFE may be configured to seal off the plurality of light-emitting diodes LD and protect the plurality of light-emitting diodes LD from external oxygen or moisture. A configuration of the encapsulation layer TFE will be described in detail in relation with other figures.

In an embodiment, the input sensor unit ISP may include a lower input sensor insulating layer LDL, a lower sensor electrode LSP, an intermediate input sensor insulating layer MDL, an upper sensor electrode USP, and an upper input sensor insulating layer UDL. The input sensor unit ISP may include a capacitive type input sensor. The input sensor unit ISP may be disposed between the encapsulation layer TFE and the light-blocking film LBL (e.g., in the third direction DR3).

The lower input sensor insulating layer LDL may be disposed on the encapsulation layer TFE (e.g., disposed directly thereon in the third direction DR3). The lower input sensor insulating layer IDL may be configured to protect the encapsulation layer TFE from an external impact. The lower input sensor insulating layer IDL may have a single layer structure or a multi-layer structure and include an inorganic material or a composite material. In an embodiment, the inorganic material may include at least one of aluminum oxide, titanium oxide, silicon oxide, silicon oxynitride, zirconium oxide, and hafnium oxide. In one or more embodiments, the lower input sensor insulating layer IDL may be replaced with an organic insulating layer. In addition, in some embodiments the lower inorganic input sensor insulating layer IDL may not be provided.

The lower sensor electrode LSP may be disposed on the lower input sensor insulating layer LDL (e.g., disposed directly thereon in the third direction DR3). The lower sensor electrode LSP may include a metallic layer or a transparent electrode. In an embodiment, the metallic layer may include molybdenum, silver, titanium, copper, aluminum, and an alloy thereof. In an embodiment, the transparent electrode may include a transparent conductive oxide, such as ITO (indium tin oxide), IZO (indium zinc oxide), ZnO (zinc oxide), or ITZO (indium tin zinc oxide).

The intermediate input sensor insulating layer MDL may be disposed on (e.g., disposed directly thereon) the lower sensor electrode LSP. The intermediate input sensor insulating layer MDL may cover the lower input sensor insulating layer LDL and the lower sensor electrode LSP. The intermediate input sensor insulating layer MDL may have a single layer structure or a multi-layer structure and include an inorganic material or a composite material. In one or more embodiments, the intermediate input sensor insulating layer MDL may be replaced with an organic insulating layer.

The upper sensor electrode USP may be disposed on (e.g., disposed directly thereon) the intermediate input sensor insulating layer MDL. A detailed configuration of the upper sensor electrode USP may be same as that of the lower sensor electrode LSP. At least some of the upper sensor electrode USP may overlap with the lower sensor electrode LSP. The upper sensor electrode USP may be electrically connected to the lower sensor electrode LSP.

The upper input sensor insulating layer UDL may cover the intermediate input sensor insulating layer MDL and the upper sensor electrode USP. The upper input sensor insulating layer UDL may have a single layer structure or a multi-layer structure and include an inorganic material or a composite material. In one or more embodiments, the upper input sensor insulating layer UDL may be replaced with an organic insulating layer.

In an embodiment, the reflection blocking layer RPL may include a light-blocking film LBL, a plurality of diffraction reduction parts DRP, a plurality of color filters CF and an upper coated layer OC. The reflection protection layer RPL may be configured to prevent reflection of external light from the display module DPM.

The light-blocking film LBL may be disposed on the input sensor unit ISP. The light-blocking film LBL may overlap with the pixel definition film PDL (e.g., in the third direction DR3). The light-blocking film LBL may have a plurality of transmission openings POP defined therein. The light-blocking film LBL may include a light-absorption material. The light-blocking film LBL may be configured to absorb incident light. Light absorbed by the light-blocking film LBL may be light having a wavelength in a visible spectrum.

In an embodiment, the plurality of transmission openings POP may include a red transmission opening POP-R, a green transmission opening POP-G, and a blue transmission opening POP-B. The plurality of transmission openings POP may respectively overlap in a plan view (e.g., in the third direction DR3) with a corresponding light-emitting diode LD among the plurality of light-emitting diodes LD. The plurality of transmission openings POP may respectively overlap in a plan view (e.g., in the third direction DR3) with a corresponding light-emission opening LOP among the plurality of light-emission openings LOP.

The plurality of transmission openings POP may be regularly disposed along a pattern. Therefore, light transmitted through the plurality of transmission openings POP may be diffracted.

The red transmission opening POP-R may overlap with the red light-emitting diode LD-R (e.g., in the third direction DR3). The red transmission opening POP-R may overlap with the light-emission opening LOP where the red light-emitting diode LD-R is disposed.

The green transmission opening POP-G may overlap with the green light-emitting diode LD-G (e.g., in the third direction DR3). The green transmission opening POP-G may overlap with the light-emission opening where the green light-emitting diode LD-G is disposed.

The blue transmission opening POP-B may overlap with the blue light-emitting diode LD-B (e.g., in the third direction DR3). The blue transmission opening POP-B may overlap with the light-emission opening LOP where the blue light-emitting diode LD-B is disposed.

A center of opening COP may be defined in each of the plurality of transmission openings POP. The center of opening may be a geometric center of mass, defined on a plane defined by the first direction DR1 and the second direction DR2 (e.g., a center of mass in a plan view), for each of the plurality of transmission openings POP.

In an embodiment, the plurality of diffraction reduction parts DRP may include a red diffraction reduction part DRP-R, a green diffraction reduction part DRP-G, and a blue diffraction reduction part DRP-B. The plurality of diffraction reduction parts DRP may be disposed in a corresponding transmission opening POP among the plurality of transmission openings POP respectively. The plurality of diffraction reduction parts DRP may not overlap with the light-blocking film LBL (e.g., in the third direction DR3).

The plurality of diffraction reduction parts DRP may include a light-absorption material. In an embodiment, a material included in the plurality of diffraction reduction parts DRP may be same as a material included in the light-blocking film LBL. The plurality of diffraction reduction parts DRP may be configured to absorb incident light. The plurality of diffraction reduction parts DRP may be arranged irregularly. The plurality of diffraction reduction parts DRP may be configured to reduce a diffraction phenomenon due to the plurality of transmission openings POP arranged regularly.

The plurality of diffraction reduction parts DRP may each have a center of diffraction reduction part COD defined therein. The center of diffraction reduction part COD may be a geometric center of mass, defined on a plane defined by the first direction DR1 and the second direction DR2, for each of the plurality of diffraction reduction parts DRP.

On a plane, the center of diffraction reduction part COD and its corresponding center of opening COP may be spaced apart from each other. The center of diffraction reduction part COD and the corresponding center of opening COP may not overlap with each other (e.g., in a plan view). In case that the center of diffraction reduction part COD and its corresponding center of opening COP are spaced apart from each other, an amount of diffraction patterns formed by light transmitted through the transmission opening POP may be further reduced. Accordingly, a diffraction pattern by light transmitted through the transmission opening POP may be less visible.

The red diffraction reduction part DRP-R may be disposed in the red transmission opening POP-R. The center of diffraction reduction part COD defined in the red diffraction reduction part DRP-R and the center of opening COP defined in the red transmission opening POP-R may be spaced apart from each other (e.g., in a plan view).

The green diffraction reduction part DRP-G may be disposed in the green transmission opening POP-G. The center of diffraction reduction part COD defined in the green diffraction reduction part DRP-G and the center of opening COP defined in the green transmission opening POP-G may be spaced apart from each other (e.g., in a plan view).

The blue diffraction reduction part DRP-B may be disposed in the blue transmission opening POP-B. The center of diffraction reduction part COD defined in the blue diffraction reduction part DRP-B and the center of opening COP defined in the blue transmission opening POP-B may be spaced apart from each other (e.g., in a plan view).

The plurality of color filters CF may include a red color filter CF-R, a green color filter CF-G, and a blue color filter CF-B. The plurality of color filters CF may overlap (e.g., in the third direction DR3) with a corresponding light-emitting diode LD among the plurality of light-emitting diodes LD respectively. The plurality of color filters CF may be disposed in a corresponding transmission opening POP among the plurality of transmission openings POP respectively. The plurality of color filters CF may cover a corresponding diffraction reduction part DRP among the plurality of diffraction reduction parts DRP respectively. The plurality of color filters CF may be configured to transmit or block incident light depending on a wavelength of incident light.

The red color filter CF-R may overlap with the red light-emitting diode LD-R (e.g., in the third direction DR3). The red color filter CF-R may be disposed in the red transmission opening POP-R. The red color filter CF-R may cover the red diffraction reduction part DPR-R. The red color filter CF-R may be configured to allow transmission of light having the first wavelength among incident light. The red color filter CF-R may be configured to block light having the second wavelength and light having the third wavelength among incident light.

The green color filter CF-G may overlap with the green light-emitting diode LD-G (e.g., in the third direction DR3). The green color filter CF-G may be disposed in the green transmission opening POP-G. The green color filter CF-G may cover the green diffraction reduction part DPR-G. The green color filter CF-G may be configured to allow transmission of light having the second wavelength among incident light. The green color filter CF-G may be configured to block light having the first wavelength and light having the third wavelength among incident light.

The blue color filter CF-B may overlap with the blue light-emitting diode LD-B (e.g., in the third direction DR3). The blue color filter CF-B may be disposed in the blue transmission opening POP-B. The blue color filter CF-B may cover the blue diffraction reduction part DPR-B. The blue color filter CF-B may be configured to allow transmission of light having the third wavelength among incident light. The blue color filter CF-B may be configured to block light having the first wavelength and light having the second wavelength among incident light.

The upper coated layer OC may be disposed on (e.g., disposed directly thereon) the plurality of color filters CF. The upper coated layer OC may be configured to protect the plurality of color filters CF. In an embodiment, the upper coated layer OC may include an organic material. For example, the upper coated layer OC may include an acrylic polymer.

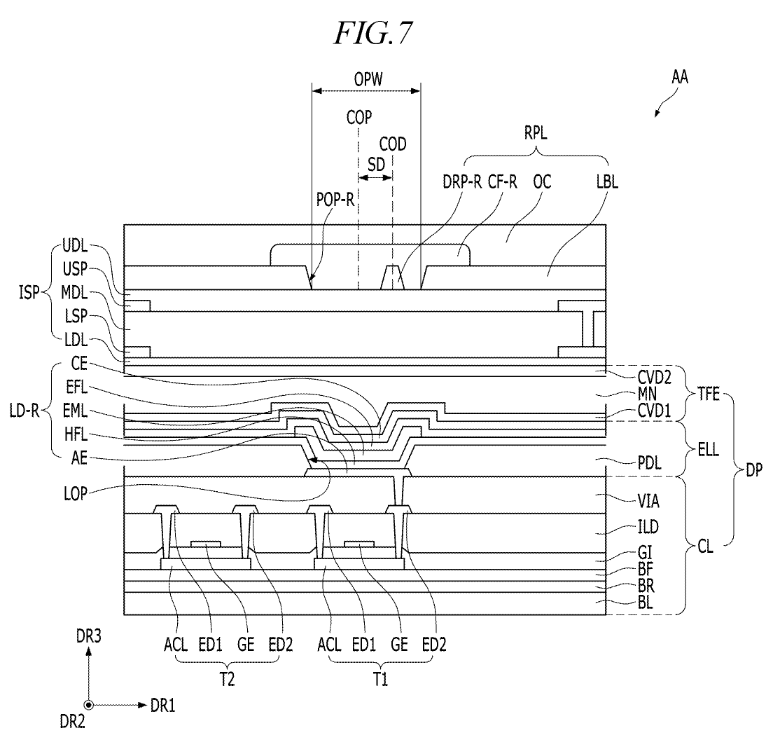

FIG. 7 is a more detailed illustration of some configurations in a magnified view of the AA section shown in FIG. 6;

Referring to FIG. 7, in an embodiment the display module DPM may include a display panel DP, an input sensor unit ISP, and a reflection protection layer RPL. In FIG. 7, a circuit layer CL, a red light-emitting diode LD-R, and an encapsulation layer TFE may be illustrated in detail in FIG. 7.

In an embodiment, the circuit layer CL may include a base member BL, a barrier layer BR, a buffer layer BF, a gate insulating layer GI, an interlayer insulating layer ILD, a circuit insulating layer VIA, a first transistor T1 and a second transistor T2.

The first transistor T1 and the second transistor T2 may be configured to transfer an electric signal. In addition, the first transistor T1 and the second transistor T2 may include a plurality of active parts ACL, a plurality of first electrodes ED1, a plurality of control electrodes GE and a plurality of second electrodes ED2.

The base member BL may be a base layer of a circuit layer CL. For example, other components of the circuit layer CL may be laminated on the base member BL. The base member BL may include an organic layer and/or an inorganic layer. The organic layer may include an organic material. For example, in an embodiment polyimide may be included. The inorganic layer may include an inorganic material.

The barrier layer BR may be disposed on the base member BL (e.g., disposed directly thereon in the third direction DR3). The barrier layer BR may be configured to prevent penetration of moisture introduced from outside. In an embodiment, the barrier layer BR may include an inorganic insulating material, such as silicon oxide and silicon nitride.

The buffer layer BF may be disposed on the barrier layer BR (e.g., disposed directly thereon in the third direction DR3). The buffer layer BF may be configured to interfere with the transfer of impurities introduced from bottom to above. Accordingly, an element disposed on the buffer layer BF may be protected. In an embodiment, the buffer layer BF may include an inorganic insulating material, such as silicon oxide and silicon nitride.

The plurality of active parts ACL may be disposed on the buffer layer BF (e.g., disposed directly thereon in the third direction DR3). In an embodiment, the plurality of active parts ACL may include polysilicon or amorphous silicon. Other than the above, the plurality of active parts ACL may include metal oxide semiconductor. The active parts ACL may include a channel area serving as a passage through which electrons or holes may move, and a first ion-doped area and a second ion-doped area disposed with the channel area therebetween.

The gate insulating layer GI may cover the buffer layer BF and the plurality of active parts ACL. The gate insulating layer GI may include an organic film and/or an inorganic film. The gate insulating layer GI may include a plurality of inorganic thin films. In an embodiment, the plurality of inorganic thin films may include a silicon nitride layer and a silicon oxide layer.

The plurality of control electrodes GE may be disposed on the buffer layer BF (e.g., disposed directly thereon in the third direction DR3). The plurality of control electrodes GE may overlap with the plurality of active parts ACL. In addition, in an embodiment the plurality of control electrodes GE may include molybdenum (Mo).

The interlayer insulating layer ILD may cover the gate insulating layer GI and a plurality of control electrodes GE. The interlayer insulating layer ILD may include an organic film and/or an inorganic film. The interlayer insulating layer ILD may include a plurality of inorganic thin films or organic thin films. In an embodiment, the plurality of inorganic thin films may include a silicon nitride layer and a silicon oxide layer.

The plurality of first electrodes ED1 and a plurality of second electrodes ED2 may be disposed on the interlayer insulating layer ILD (e.g., disposed directly thereon in the third direction DR3). In an embodiment, the plurality of first electrodes ED1 and the plurality of second electrodes ED2 may be electrically connected to the plurality of active parts ACL through a plurality of contact holes defined on the interlayer insulating layer ILD. In addition, the plurality of first electrodes ED1 and the plurality of second electrodes ED2 may include a metal.

The circuit insulating layer VIA may cover the interlay insulating layer ILD, the plurality of first electrodes ED1 and the plurality of second electrodes ED2. The circuit insulating layer VIA may include an organic film and/or an inorganic film. In an embodiment, the circuit insulating layer VIA may provide a flat surface. However, in some embodiments, an amount of the circuit insulating layer VIA may be increase as necessary and may not provide a flat surface.

The red light-emitting diode LD-R may include an anode electrode AE, a hole functional layer HFL, a light-emission layer EML, an electron functional layer EFL, and a cathode electrode CE. In one or more embodiments, the red light-emitting diode LD-G and the blue light-emitting diode LD-B shown in FIG. 6 may have a same layer structure as the red light-emitting diode LD-R.

The anode electrode AE may be disposed on a portion of the circuit insulating layer VIA (e.g., disposed directly thereon in the third direction DR3). Particularly, the anode electrode AE may be exposed by the plurality of light-emission openings LOP. In addition, the anode electrode AE may be electrically connected to any one of the plurality of second electrodes ED2 through a contact hole defined in the circuit insulating layer VIA. Accordingly, the anode electrode AE may be configured to receive an electric signal from the first transistor T1 and the second transistor T2.

Although FIG. 7 illustrates the first transistor T1 and the second transistor T2, structures of the first transistor T1 and the second transistor T2 are not necessarily limited thereto. Although FIG. 7 is illustrated as if the first transistor T1 makes direct contact with the anode electrode AE through any one of the plurality of second electrodes ED2, this is due to the cross-sectional view, and in reality, the first transistor T1 may be connected to the anode electrode AE through another transistor. However, embodiments of the present disclosure are not necessarily limited thereto, and in an embodiment of the present disclosure, the first transistor T1 may make direct contact with the anode electrode AE through any one of the plurality of second electrodes ED2.

The hole functional layer HFL may be disposed on the anode electrode AE (e.g., disposed directly thereon in the third direction DR3). The hole functional layer HFL may be configured to support transfer of a hole generated from the anode electrode AE. For example, in an embodiment the hole functional layer HFL may be configured to more readily receive a hole injected from the anode electrode AE and facilitate the transfer of the hole. The hole functional layer HFL may have a multi-layer structure. For example, a hole injection layer and a hole transfer layer may be further included.

The light-emission layer EML may be disposed on (e.g., disposed directly thereon) the hole functional layer HFL. The light-emission layer EML may emit light. In an embodiment, the light-emission layer EML may include, for example, an organic light-emitting material or a quantum dot. Accordingly, the light-emitting diode LD may be an organic light-emitting diode or a quantum dot light-emitting diode.

The electron functional layer EFL may be disposed on (e.g., disposed directly thereon) the light-emission layer EML. The electron functional layer EFL may be configured to support transfer of an electron generated from the cathode electrode CE. For example, the electron functional layer EFL may be configured to more readily receive an electron injected from the cathode electrode CE and facilitate the transfer of the electron. The electron functional layer EFL may have a multi-layer structure. For example, in some embodiments an electron injection layer and an electron transfer layer may be further included.

The cathode electrode CE may be disposed on (e.g., disposed directly thereon) the electron functional layer EFL. The cathode electrode CE has a low resistance, and thus current may readily flow. The cathode electrode CE may be a shared electrode. Therefore, in some embodiments the plurality of light-emitting diodes LD1, LD2, LD3 shown in FIG. 7 may share a cathode electrode CE.

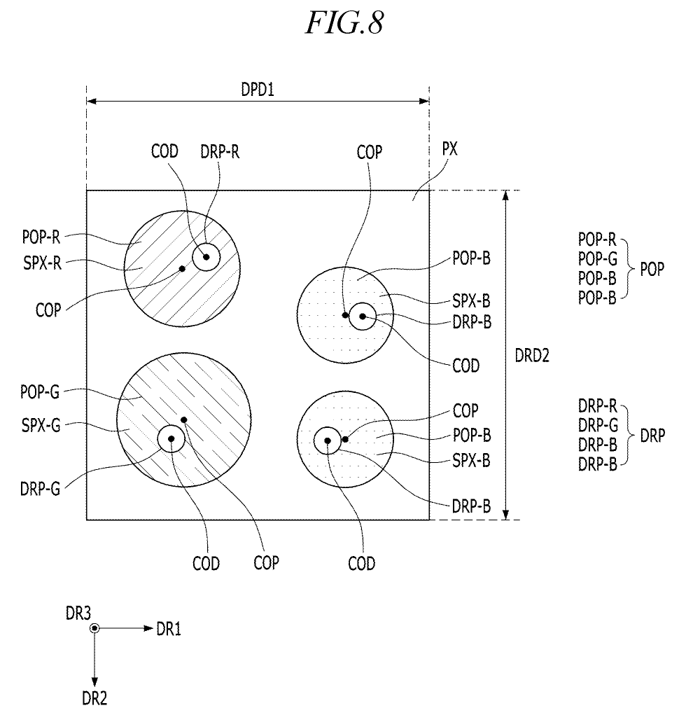

In an embodiment, the encapsulation layer TFE may include a first encapsulation inorganic layer CVD1, an encapsulation organic layer MN, a second encapsulation inorganic layer CVD2. While the encapsulation layer TFE in FIG. 8 is illustrated to include two inorganic encapsulation layers CVD1, and CVD2, and one organic encapsulation layer MN, embodiments of the present disclosure are not necessarily limited to this configuration. For example, in some embodiments the encapsulation layer TFE may include three inorganic encapsulation layers and two organic encapsulation layers, in which case the inorganic encapsulation layers and the organic encapsulation layers may be alternately laminated (e.g., in the third direction DR3).

In FIG. 7, an opening width OPW and a spacing distance SD may be further illustrated. The opening width OPW may be defined as a width of the red transmission opening POP-R (e.g., in a plan view). The spacing distance SD may be defined as a distance between the center of opening COP and the center of diffraction reduction part COD in a plan view. In an embodiment, the spacing distance SD may be in a range of about 0.02 times to about 0.32 times the size of the opening width OPW. In case that the spacing distance SD is less than about 0.02 times the size of the opening width OPW, effects of reducing diffraction phenomenon by the red diffraction reduction part DRP-R may be limited. In case that the spacing distance SD is greater than about 0.32 times of the opening width OPW, at least some of the red diffraction reduction part DRP-R may not be disposed in the red transmission opening POP-R.

Although FIG. 7 merely illustrates opening widths OPW of the red transmission opening POP-R and the red diffraction reduction part DRP-R and the spacing distance SD for economy of illustration, the opening width OPW and the spacing distance SD may be similarly defined for the green transmission opening POP-G and the green diffraction reduction part DRP-G shown in FIG. 6. In addition, the opening width OPW and the spacing distance SD may be similarly defined for the blue transmission opening POP-B and the blue diffraction reduction part DRP-B shown in FIG. 6.

FIG. 8 is a plan view of any one of the plurality of pixels PX according to an embodiment of the present disclosure.

Referring to FIG. 8, in an embodiment the pixel PX may include a red sub-pixel SPX-R, a green sub-pixel SPX-G, and two blue sub-pixels SPX-B. In FIG. 8, the plurality of transmission openings POP and the plurality of diffraction reduction parts DRP may be illustrated. The pixel PX may extend by a first pixel distance DPD1 in the first direction DR1 and by a second pixel distance DPD2 in the second direction DR2.

The red sub-pixel SPX-R may be defined by the red transmission opening POP-R. The red sub-pixel SPX-R may be configured to emit light having the first wavelength. A center of mass of the red transmission opening POP-R may be illustrated as (e.g., defined as) the center of opening COP, and a center of mass of the red diffraction reduction part DRP-R may be illustrated as (e.g., defined as) the center of diffraction reduction part COD.

In a plan view, the center of mass of the red diffraction reduction part DRP-R may be spaced apart from the center of mass of the red transmission opening POP-R. The center of mass of the red diffraction reduction part DRP-R may be spaced apart from the center of mass of the red transmission opening POP-R in the red-part spacing direction by the red-part spacing distance.

In a plan view, a value obtained by dividing an area of the red diffraction reduction part DRP-R by an area of the red transmission opening POP-R may be defined as a red-part area ratio. In an embodiment, the red-part area ratio may be in a range of about 0.05 to about 0.20. In case that the red-part area ratio is less than 0.05, the effects of reducing diffraction phenomenon by the red diffraction reduction part DRP-R may be limited. In case that the red-part area ratio is greater than 0.20, light having the first wavelength may be absorbed by the red diffraction reduction part DRP-R, and light-emission efficiency of light having the first wavelength may be reduced.

The green sub-pixel SPX-G may be defined by the green transmission opening POP-G. The green sub-pixel SPX-G may be configured to emit light having the second wavelength. A center of mass of the green transmission opening POP-G may be illustrated as (e.g., defined as) the center of opening COP, and a center of mass of the green diffraction reduction part DRP-G may be illustrated as (e.g., defined as) a center of mass of diffraction reduction part COD.

In a plan view, the center of mass of the green diffraction reduction part DRP-G may be spaced apart from the center of mass of the green transmission opening POP-G. The center of mass of the green diffraction reduction part DRP-G may be spaced apart from the center of mass of the green transmission opening POP-G by the green-part spacing distance in the green-part spacing direction. In an embodiment, the green-part spacing direction may be different from the red-part spacing direction. In an embodiment, the green-part spacing distance may be different from the red-part spacing distance.

In a plan view, a value obtained by dividing an area of the green diffraction reduction part DRP-G by an area of the green transmission opening POP-G may be defined as a green-part area ratio. In an embodiment, the green-part area ratio may be in a range of about 0.05 to about 0.20. In case that the green-part area ratio is less than 0.05, the effects of reducing a diffraction phenomenon by the green diffraction reduction part DRP-G may be limited. In case that the green-part area ratio is greater than 0.20, light having the second wavelength may be absorbed by the green diffraction reduction part DRP-G, and light-emission efficiency of light having the second wavelength may be reduced. The green-part area ratio and the red-part area ratio may be substantially same.

The plurality of blue sub-pixels SPX-B may be defined by the plurality of blue transmission openings POP-B. The plurality of blue sub-pixels SPX-B may be configured to emit light having the third wavelength. A center of mass of each of the plurality of blue transmission openings POP-B may be illustrated as (e.g., defined as) a center of opening COP, and a center of mass of each of the plurality of blue diffraction reduction parts DRP-B may be illustrated as (e.g., defined as) a center of diffraction reduction part COD.

In a plan view, the center of mass of each of the plurality of blue diffraction reduction parts DRP-B may be spaced apart from the center of mass of its corresponding blue transmission opening POP-B. The center of mass of each of the plurality of blue diffraction reduction parts DRP-B may be spaced apart from the center of mass of its corresponding blue transmission opening POP-B by a blue-part spacing distance in the blue-part spacing direction. In an embodiment, the blue-part spacing direction may be different from the red-part spacing direction and the green-part spacing direction. In an embodiment, the blue-part spacing distance may be different from the red-part spacing distance and the green-part spacing distance.

A blue-part spacing direction and a blue-part spacing distance of any one of the plurality of blue diffraction reduction parts DRP-B may be different from a blue-part spacing direction and a blue-part spacing distance of another of the plurality of blue diffraction reduction parts DRP-B.

In a plan view, a value obtained by dividing an area of each of the plurality of blue diffraction reduction parts DRP-B by an area of its corresponding blue transmission opening POP-B may be defined as a blue-part area ratio. In an embodiment, the blue-part area ratio may be in a range of about 0.05 to about 0.20. In case that the blue-part area ratio is less than about 0.05, the effects of reducing diffraction phenomenon by the blue diffraction reduction part DRP-B may be limited. In case that the blue-part area ratio is greater than about 0.20, light having the third wavelength may be absorbed by the blue diffraction reduction part DRP-B, and light-emission efficiency of light having the third wavelength may be reduced. In an embodiment, the blue-part area ratio may be smaller than the red-part area ratio and the green-part area ratio.

As a result, a center of mass of each of the plurality of diffraction reduction parts DRP positioned in one pixel PX may be spaced apart from a center of mass of its corresponding transmission opening POP in different directions by different distances. Therefore, the plurality of diffraction reduction parts DRP may be irregularly disposed, and diffraction phenomenon may be reduced.

In FIG. 8, the plurality of transmission openings POP and the plurality of diffraction reduction parts DRP shown in FIG. 8 are each illustrated to have a circular shape (e.g., in a plan view). However, each shape of the plurality of transmission openings POP and the plurality of diffraction reduction parts DRP is not necessarily limited thereto. The plurality of transmission openings POP and the plurality of diffraction reduction parts DRP may each have a shape of, for example, a rectangle, a trapezoid, a polygon, etc. (in a plan view).

FIG. 8 illustrates that the pixel PX includes one red sub-pixel SPX-R, one green sub-pixel SPX-G, and two blue sub-pixels SPX-B, but a configuration of the pixel PX is not necessarily limited thereto.

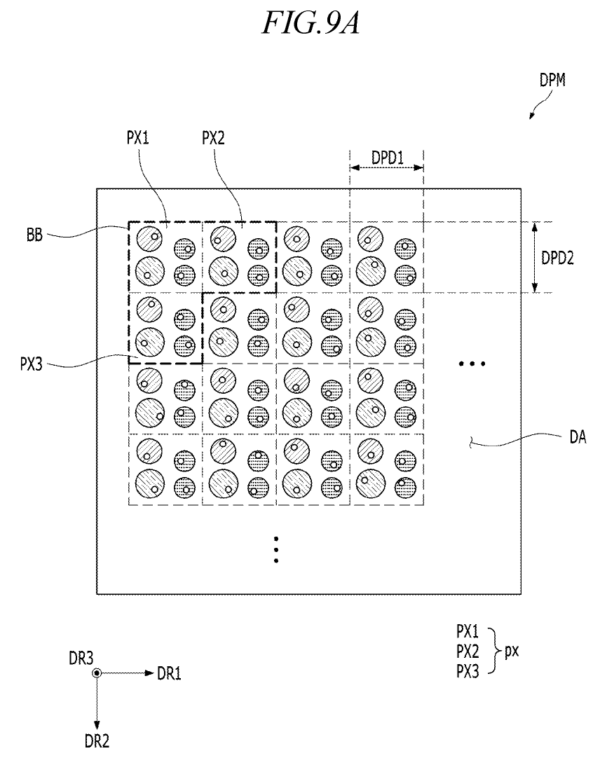

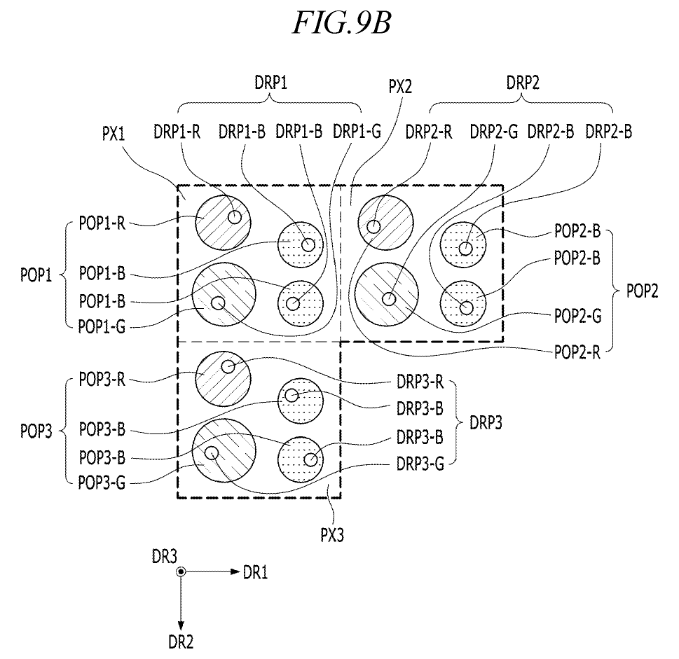

FIG. 9A is an illustration of a plan view of a display module DPM according to an embodiment of the present disclosure. FIG. 9B is a magnified view of the BB section shown in FIG. 9A.

Referring to FIGS. 9A and 9B, a plurality of pixels PX are disposed in the display module DPM. The plurality of pixels PX may be arranged at a first pixel distance DPD1 in the first direction DR1 and at a second pixel distance DPD2 in the second direction DR2. In an embodiment, the plurality of pixels PX may include a first pixel PX1, a second pixel PX2, and a third pixel PX3. However, embodiments of the present disclosure are not necessarily limited thereto and the number of the plurality of pixels may vary.

The plurality of pixels PX may each have a plurality of transmission openings POP1, POP2, POP3 defined therein. In an embodiment, the plurality of transmission openings POP1, POP2, POP3 defined in each of the plurality of pixels PX may be defined along a pre-determined pattern. Therefore, shapes of a plurality of transmission openings POP1, POP2, POP3 defined in any one of the plurality of pixels PX may be identical to shapes of a plurality of transmission openings POP1, POP2, POP3 defined in another of the plurality of pixels PX.

A plurality of diffraction reduction parts DRP1, DRP2, DRP3 may be disposed in each of the plurality of pixels PX. In an embodiment, the plurality of diffraction reduction parts DRP1, DRP2, DRP3 disposed in each of the plurality of pixels PX may not be arranged along a pattern. A plurality of diffraction reduction parts DRP1, DRP2, DRP3 disposed in any one of the plurality of pixels PX may have different shapes from a plurality of diffraction reduction parts disposed in another of the plurality of pixels PX.

As described herein, an expression “shapes of a plurality of elements” may have a concept including a shape of each of the plurality elements and a position relationship among the plurality of elements (e.g., in a plan view). For example, in case that “a plurality of first elements” and “a plurality of second elements” are compared in terms of a shape, and if shapes of each of the plurality of first elements and shapes of each of the plurality of second elements are the same as each other (e.g., in a plan view) and position relationship among the plurality of first elements and position relation among the plurality of second elements are the same as each other (e.g., in a plan view), the plurality of first elements and the plurality of second elements may be determined to have a same shape as each other.

A plurality of first transmission openings POP1 may be defined in the first pixel PX1. In an embodiment, the plurality of first transmission openings POP1 may include a first red transmission opening POP1-R, a first green transmission opening POP1-G, and a plurality of first blue transmission openings POP1-B. In the present disclosure, the first transmission opening POP1 may be any one of the first red transmission opening POP1-R, the first green transmission opening POP1-G, and the plurality of first blue transmission openings POP1-B.

A plurality of second transmission openings POP2 may be defined in the second pixel PX2. In an embodiment, the plurality of second transmission openings POP2 may include a second red transmission opening POP2-R, a second green transmission opening POP2-G, and a plurality of second blue transmission openings POP2-B. In the present disclosure, the second transmission opening POP2 may be any one of the second red transmission opening POP2-R, the second green transmission opening POP2-G, and the plurality of second blue transmission openings POP2-B.

The second pixel PX2 may be spaced apart from the first pixel PX1 in the first direction DR1. A center of mass of each of the plurality of second transmission openings POP2 may be spaced apart from a center of mass of its corresponding first transmission opening POP1 among the plurality of first transmission openings POP1 by a first arrangement distance in a first arrangement direction. In an embodiment, the first arrangement direction may be the first direction DR1. The first arrangement distance may be the first pixel distance DPD1.

In an embodiment, a center of mass of the second red transmission opening POP2-R may be spaced apart from a center of mass of the first red transmission opening POP1-R by the first arrangement distance in the first arrangement direction. A center of mass of the second green transmission opening POP2-G may be spaced apart from a center of mass of the first green transmission opening POP1-G by the first arrangement distance in the first arrangement direction. A center of mass of each of the plurality of second blue transmission openings POP2-B may be spaced apart from a center of mass of its corresponding first blue transmission opening POP1-B by the first arrangement distance in the first arrangement direction.

Therefore, the plurality of second transmission openings POP2 may be defined as being parallel-shifted from the plurality of first transmission openings POP1 by the first arrangement in the first arrangement direction. As a result, shapes of the plurality of second transmission openings POP2 defined in the second pixel PX1 may be same as shapes of the plurality of first transmission openings POP1 defined in the first pixel PX1.

A plurality of third transmission openings POP3 may be defined in the third pixel PX3. In an embodiment, the plurality of third transmission openings POP3 may include a third red transmission opening POP3-R, a third green transmission opening POP3-G, and a plurality of third blue transmission openings POP3-B. In the present disclosure, a third transmission opening POP3 may be any one of the third red transmission opening POP3-R, the third green transmission opening POP3-G, and the plurality of third blue transmission openings POP3-B.

The third pixel PX3 may be a pixel disposed to be spaced apart from the first pixel PX1 in the second direction DR2. A center of mass of each of the plurality of third transmission openings POP3 may be spaced apart from a center of mass of its corresponding first transmission opening POP1 among the plurality of first transmission openings POP1 by a second arrangement distance in a second arrangement direction. In an embodiment, the second arrangement direction may be the second direction DR2. The second arrangement distance may be the second pixel distance DPD2.

In an embodiment, a center of mass of the third red transmission opening POP3-R may be spaced apart from a center of mass of the first red transmission opening POP1-R by the second arrangement distance in the second arrangement direction. A center of mass of the third green transmission opening POP3-G may be spaced apart from a center of mass of the first green transmission opening POP1-G by the second arrangement distance in the second arrangement direction. A center of mass of each of the plurality of third blue transmission openings POP3-B may be spaced apart from a center of mass of its corresponding first blue transmission opening POP1-B among the plurality of first blue transmission openings POP1-B by the second arrangement distance in the second arrangement direction.

Therefore, the plurality of third transmission openings POP3 may be defined as being parallel-shifted from the plurality of first transmission openings POP1 by the second arrangement in the second arrangement direction. Shapes of the plurality of third transmission openings POP3 defined in the third pixel PX3 may be same as the shapes of the plurality of first transmission openings POP1 defined in the first pixel PX1.

A plurality of first diffraction reduction parts DRP1 may be disposed in the first pixel PX1. In an embodiment, the plurality of first diffraction reduction parts DRP1 may include a first red diffraction reduction part DRP1-R, a first green diffraction reduction part DRP1-G, and a plurality of first blue diffraction reduction parts DRP1-B. In the present disclosure, the first diffraction reduction part DRP1 may be any one of the first green diffraction reduction part DRP1-R, the first green diffraction reduction part DRP1-G, and the plurality of first blue diffraction reduction parts DRP1-B.

A plurality of second diffraction reduction parts DRP2 may be disposed in the second pixel PX2. In an embodiment, the plurality of second diffraction reduction parts DRP2 may include a second red diffraction reduction part DRP2-R, a second green diffraction reduction part DRP2-G, and a plurality of second blue diffraction reduction parts DRP2-B. In the present disclosure, the second diffraction reduction part DRP2 may be any one of the second red diffraction reduction part DRP2-R, the second green diffraction reduction part DRP2-G, and the plurality of second blue diffraction reduction parts DRP2-B.

The second pixel PX2 may be a pixel disposed to be spaced apart from the first pixel PX1 in the first direction DR1. In an embodiment, a center of mass of each of the plurality of second diffraction reduction parts DRP2 may be spaced apart from a center of mass of its corresponding first diffraction reduction parts DRP1 among the plurality of first diffraction reduction parts DRP1 by a distance different from the first arrangement distance and in a direction different from the first arrangement direction.

For example, in an embodiment a center of mass of the second red diffraction reduction part DRP2-R may be spaced apart from a center of mass of the first red diffraction reduction part DRP1-R by a distance different from the first arrangement distance in a direction different from the first arrangement direction. A center of mass of the second green diffraction reduction part DRP2-G may be spaced apart from a center of mass of the first green diffraction reduction part DRP1-G by a distance different from the first arrangement distance in a direction different from the first arrangement direction. A center of mass of each of the plurality of second blue diffraction reduction parts DRP2-B may be spaced apart from a center of mass of its corresponding first blue diffraction reduction part DRP1-B among the plurality of first blue diffraction reduction parts DRP1-B by a distance different from the first arrangement distance in a direction different from the first arrangement direction.

Therefore, the plurality of second diffraction reduction parts DRP2 may each be disposed to be shifted from its corresponding first diffraction reduction part DRP1 among the plurality of first diffraction reduction parts DRP1 by a distance different from the first arrangement distance and in a direction different from the first arrangement direction. As a result, the plurality of second diffraction reduction parts DRP2 disposed in the second pixel PX2 may have different shapes from the plurality of first diffraction reduction parts DRP1 disposed in the first pixel PX1.

A plurality of third diffraction reduction parts DRP3 may be defined in the third pixel PX3. In an embodiment, the plurality of third diffraction reduction parts DRP3 may include a third red diffraction reduction part DRP3-R, a third green diffraction reduction part DRP3-G, and a plurality of third blue diffraction reduction parts DRP3-B. In the present disclosure, a third diffraction reduction part DRP3 may be any one of the third red diffraction reduction part DRP3-R, the third green diffraction reduction part DRP3-G, and the plurality of third blue diffraction reduction parts DRP3-B.

The third pixel PX3 may be a pixel disposed to be spaced apart from the first pixel PX1 in the second direction DR2. A center of mass of each of the plurality of third diffraction reduction parts DRP3 may be spaced apart from a center of mass of its corresponding first diffraction reduction parts DRP1 among the plurality of first diffraction reduction parts DRP1 by a distance different from the second arrangement distance in a direction different from the second arrangement direction.

For example, in an embodiment a center of mass of the third red diffraction reduction parts DRP3-R may be spaced apart from a center of the first red diffraction reduction part DRP1-R by a distance different from the second arrangement distance and in a direction different from the second arrangement direction. A center of mass of the third green diffraction reduction part DRP3-G may be spaced apart from a center of mass of the first green diffraction reduction part DRP1-G by a distance different from the second arrangement distance and in a direction different from the second arrangement direction. A center of mass of each of the plurality of third blue diffraction reduction parts DRP3-B may be spaced apart from a center of mass of its corresponding first blue diffraction reduction part DRP1-B among the plurality of first blue diffraction reduction parts DRP1-B by a distance different from the second arrangement distance and in a direction different from the second arrangement direction.

Therefore, each of the plurality of third diffraction reduction parts DRP3 may be disposed to be shifted from its corresponding first diffraction reduction part DRP1 among the plurality of first diffraction reduction parts DRP1 by a distance different from the second arrangement distance and in a direction different from the second arrangement direction. As a result, the plurality of third diffraction reduction parts DRP3 disposed in the third pixel PX3 may have different shapes from the plurality of first diffraction reduction parts DRP1 disposed in the first pixel PX1.

As a result, the plurality of pixels PX may each have a different shape by the plurality of diffraction reduction parts DRP1, DRP2, DRP3. As a result, a diffraction pattern generated from the plurality of pixels PX may be reduced by the plurality of diffraction reduction parts DRP1, DRP2, DRP3.

However, in a comparative embodiment in which a plurality of diffraction reduction parts DRP1, DRP2, DRP3 are not provided, a plurality of pixels PX may each have a same shape by the plurality of transmission openings POP1, POP2, POP3. As a result, a diffraction pattern may be generated by the plurality of pixels PX.

In an embodiment, a color filter corresponding to each of the plurality of transmission openings POP1, POP2, POP3 may be disposed in the first to third pixels PX1 to PX3. For example, a first color filter may be disposed in each of the plurality of first transmission openings POP1. The first color filter may cover any one of the plurality of first diffraction reduction parts DRP1.

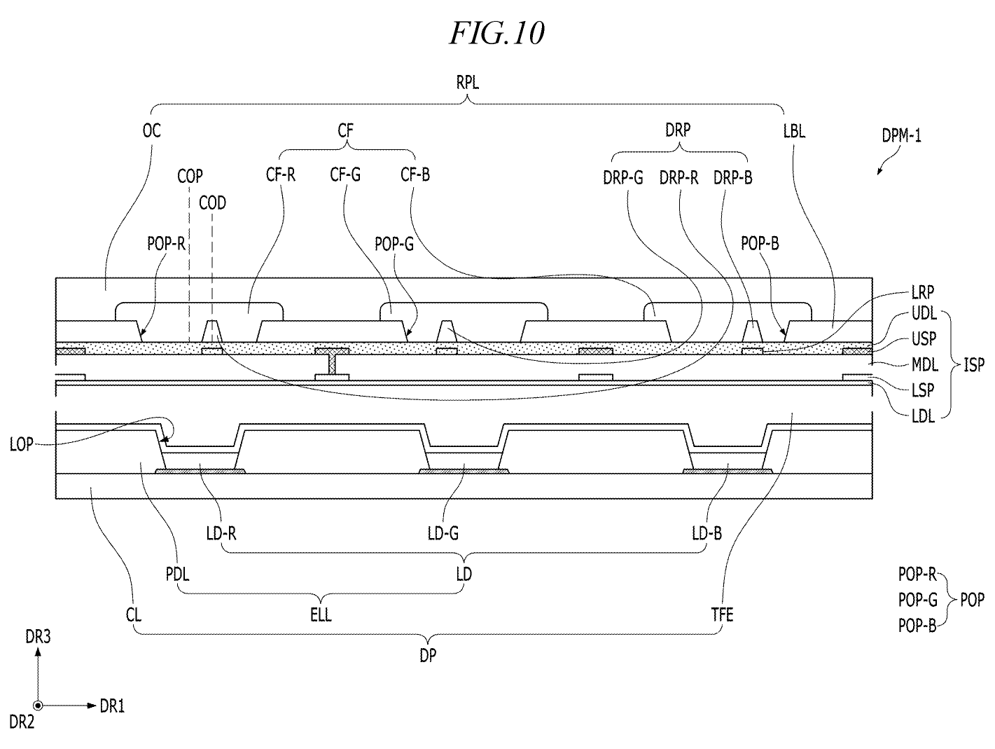

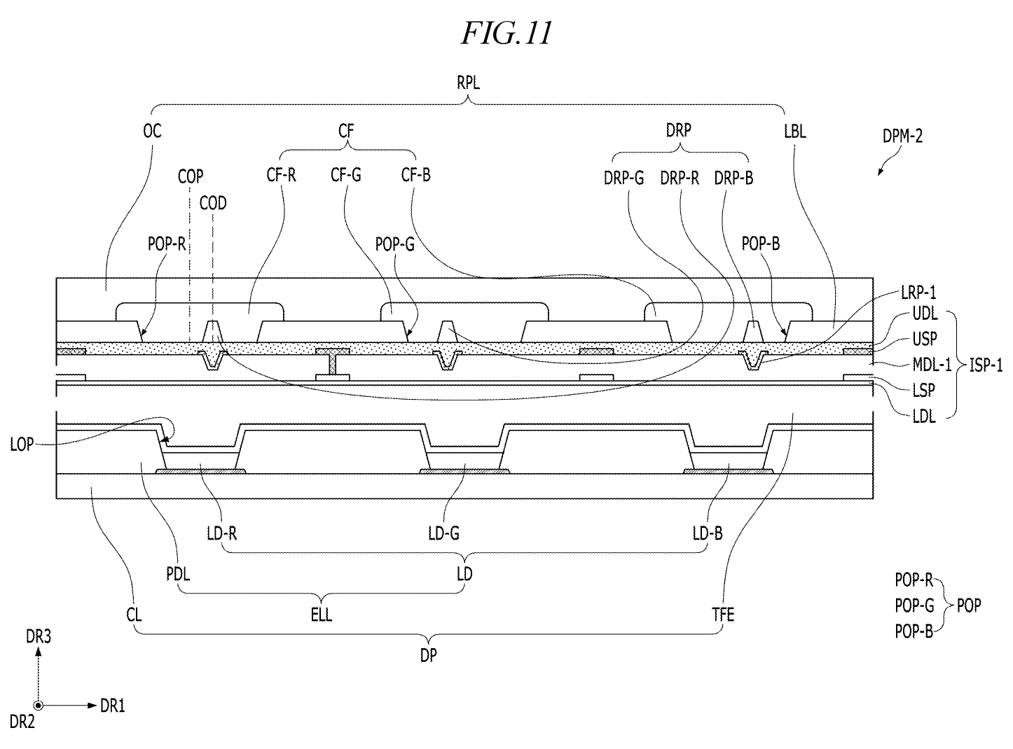

FIG. 10 is a cross-sectional view of a display module DPM-1 according to an embodiment of the present disclosure.

Referring to FIG. 10, the display module DPM-1 may further include a light-reflection part LRP (e.g., a light reflection unit). The light-reflection part LRP may be configured to reflect incident light.

The light-reflection part LRP may overlap with the plurality of light-emitting diodes LD (e.g., in the third direction DR3). The light-reflection part LRP may overlap with the plurality of diffraction reduction parts DRP. The light-reflection part LRP may be disposed between the intermediate input sensor insulating layer MDL and the upper input sensor insulating layer UDL (e.g., in the third direction DR3).

Light emitted from the plurality of light-emitting diodes LD may be reflected from the light-reflection part LRP towards a lower portion. The reflected light from the light-reflection part LRP towards the lower portion may be reflected from the cathode electrode of the plurality of light-emitting diodes LD towards an upper portion. The light-reflection part LRP may be configured to reflect light towards the plurality of diffraction reduction parts DRP. Therefore, due to the light-reflection part LRP, light incident on and absorbed by the plurality of diffraction reduction parts DRP may be reduced. The light-reflection part LRP may increase light-emission efficiency of the display module DPM-1.

In an embodiment, the light-reflection part LRP may include a same material as the upper sensor electrode USP. In an embodiment, the light reflection part LRP may be formed during a process of forming the upper sensor electrode USP. Therefore, the light-reflection part LRP may be easily formed without an individual additional process.

FIG. 11 is a cross-sectional view of the display module DPM-2 according to an embodiment of the present disclosure.

Referring to FIG. 11, a groove part may be defined in the intermediate input sensor insulating layer MDL-1. The light-reflection part LRP-1 may be disposed in the groove part defined in the intermediate input sensor insulating layer MDL-1.

The light-reflection part LRP-1 may be disposed in the groove part defined in the intermediate input sensor insulating layer MDL-1, and light reflected by the light-reflection part LRP-1 may be diffused. Therefore, light may be reflected by the light-reflection part LRP-1 and the cathode electrode of the plurality of light-emitting diodes LD to prevent a phenomenon where the display module DPM-2 appears bright as a specific viewing angle.

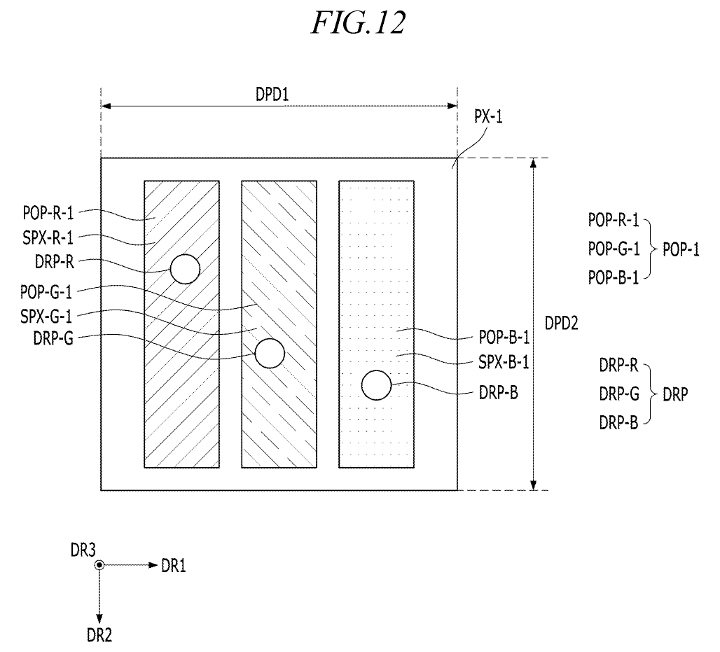

FIG. 12 is a plan view of any one of the plurality of pixels PX-1 according to an embodiment of the present disclosure.

Referring to FIG. 12, in an embodiment the pixel PX-1 may include a red sub-pixel SPX-R-1, a green sub-pixel SPX-G-1, and a blue sub-pixel SPX-B-1. The pixel PX-1 may be a pixel PX-1 having a stripe pattern.

In a plan view, the red sub-pixel SPX-R-1 may have a rectangular shape having long sides extending in the second direction DR2. The green sub-pixel SPX-G-1 may have a rectangular shape having long sides extending in the second direction DR2. The green sub-pixel SPX-G-1 may be defined to be spaced apart from the red sub-pixel SPX-R-1 in the first direction DR1. The blue sub-pixel SPX-B-1 may have a rectangular shape having long sides extending in the second direction DR2. The blue sub-pixel SPX-B-1 may be defined to be spaced apart from the green sub-pixel SPX-G-1 in the first direction DR1.

The red transmission opening POP-R-1 may have a red sub-pixel SPX-R-1 defined therein. The green transmission opening POP-G-1 may have a green sub-pixel SPX-G-1 defined therein. The blue transmission opening POP-B-1 may have a blue sub-pixel SPX-B-1 defined therein.

In a plan view, the plurality of transmission openings POP-1 may each have a rectangular shape. In a plan view, the plurality of diffraction reduction parts DPR may each have a circular shape. In a plan view, even in case that the plurality of transmission openings POP-1 each has a rectangular shape, a corresponding diffraction reduction part DPR among the plurality of diffraction reduction parts DRP may be disposed in each of the plurality of transmission openings POP-1 to reduce diffraction phenomenon due to the plurality of transmission openings POP-1.

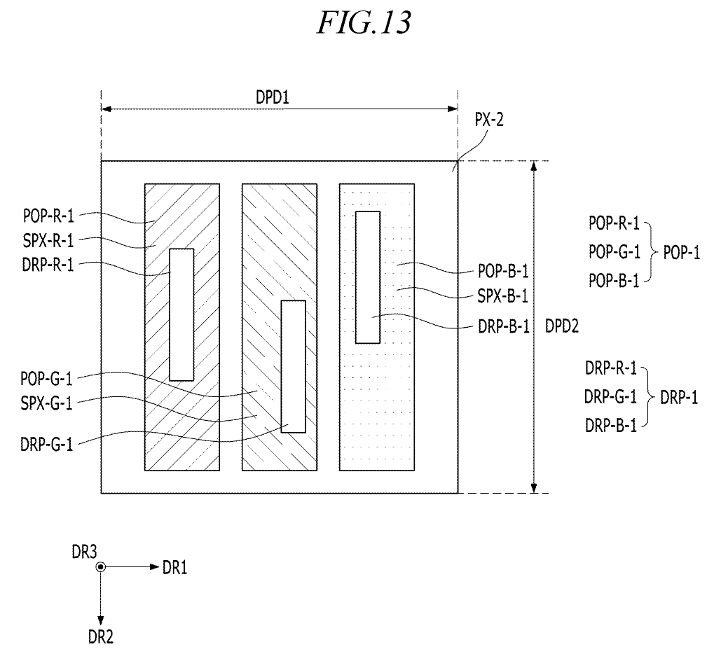

FIG. 13 is a plan view of any one of the plurality of pixels PX-2 according to an embodiment of the present disclosure.

Referring to FIG. 13, the plurality of diffraction reduction parts DRP-1 may each have a rectangular shape in a plan view having long sides extending in the second direction DR2. In a plan view, the plurality of transmission openings POP-b may each have a rectangular shape having long sides extending in the second direction DR2.

Even in case that the plurality of diffraction reduction parts DRP-1 each has a non-circular shape, a corresponding diffraction reduction part DPR-1 among the plurality of diffraction reduction parts DRP-1 may be disposed in each of the plurality of transmission openings POP-1 to reduce a diffraction phenomenon due to the plurality of transmission openings POP-1.

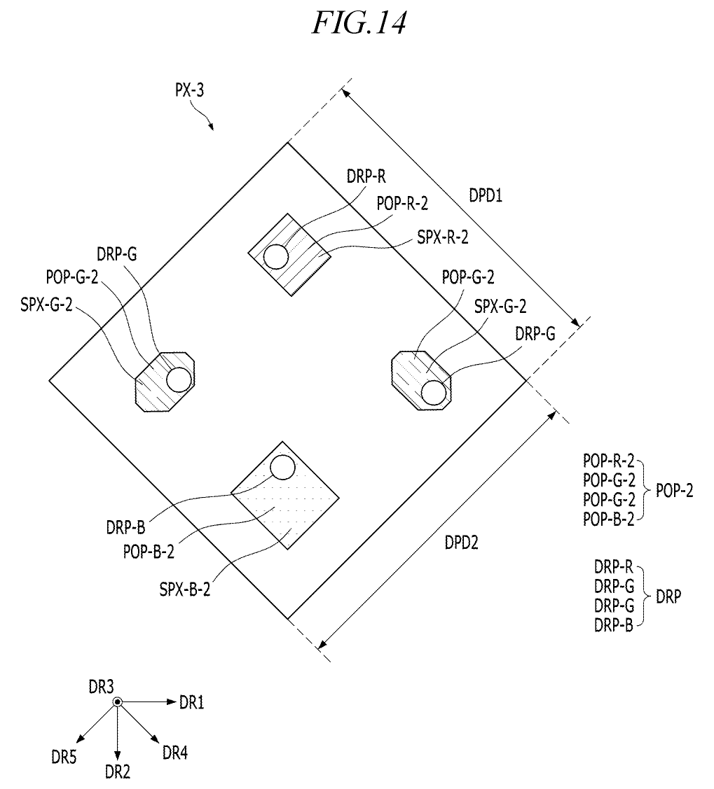

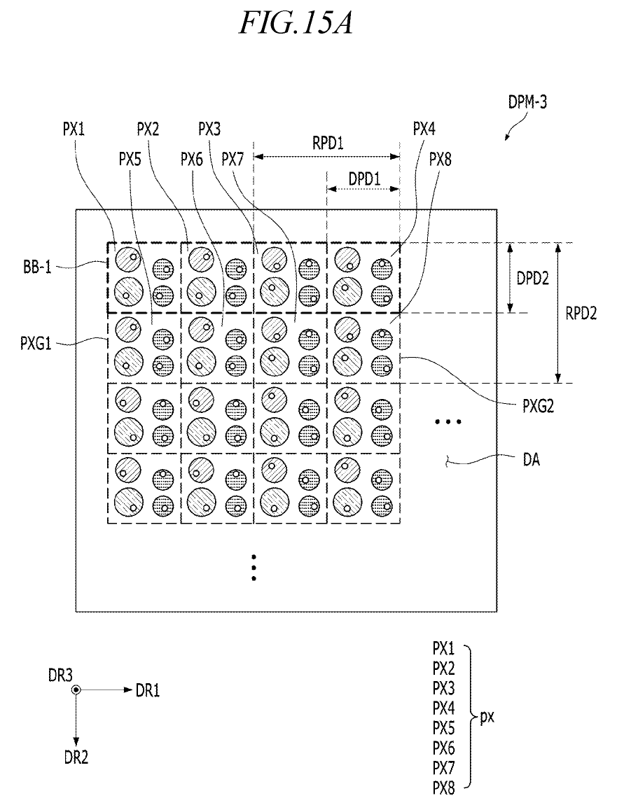

FIG. 14 is a plan view of any one of the plurality of pixels PX-3 according to an embodiment of the present disclosure.

Referring to FIG. 14, in an embodiment the pixel PX-3 may include a red sub-pixel SPX-R-2, two green sub-pixels SPX-G-2, and a blue sub-pixel SPX-B-2. The pixel PX-3 may be a pixel PX-3 of a diamond pentile pattern.

In FIG. 14, a direction pointed by a fourth directional axis DR4 may be defined as a fourth direction DR4. In addition, a direction pointed by a fifth directional axis DR5 may be defined as a fifth direction DR5. The fourth direction DR4 and the fifth direction DR5 are diagonal directions between the first and second directions DR1, DR1. In some embodiments, the fourth direction DR4 and the fifth direction DR5 may be diagonal with each other. However, embodiments of the present disclosure are not necessarily limited thereto.

In a plan view, the red sub-pixel SPX-R-2 may have a quadrilateral shape extending in the fourth direction DR4 and the fifth direction DR5. The two green sub-pixels SPX-G-2 may have a polygonal shape (e.g., in a plan view). Any one of the green sub-pixels SPX-G-2 may be defined to be spaced apart from the red sub-pixel SPX-R-2 in the fourth direction DR4. The other of the green sub-pixels SPX-G-2 may be defined to be spaced apart from the red sub-pixel SPX-R-2 in the fifth direction DR5. The blue sub-pixel SPX-B-2 may have a quadrilateral shape extending in the fourth direction DR4 and the fifth direction DR5. The blue sub-pixel SPX-B-2 may be defined to be spaced apart from the red sub-pixel SPX-R-1 in the second direction.

The red transmission opening POP-R-2 may have a red sub-pixel SPX-R-2 defined therein. Each of the plurality of green transmission openings POP-G-2 may have a corresponding green sub-pixel SPX-G-2 among the plurality of green sub-pixels SPX-G-2 defined therein. The blue transmission opening POP-B-2 may have a blue sub-pixel SPX-B-2 defined therein.

In a plan view, the plurality of transmission openings POP-2 may each have a quadrilateral or polygonal shape. In a plan view, even in case the plurality of transmission openings POP-2 each has a quadrilateral or polygonal shape, a corresponding diffraction reduction part DRP among the plurality of diffraction reduction parts DRP may be disposed in each of the plurality of transmission openings POP-2 to reduce diffraction phenomenon due to the plurality of transmission openings POP-2. In an embodiment, each of the plurality of diffraction reduction parts DPR may have a circular shape (e.g., in a plan view).

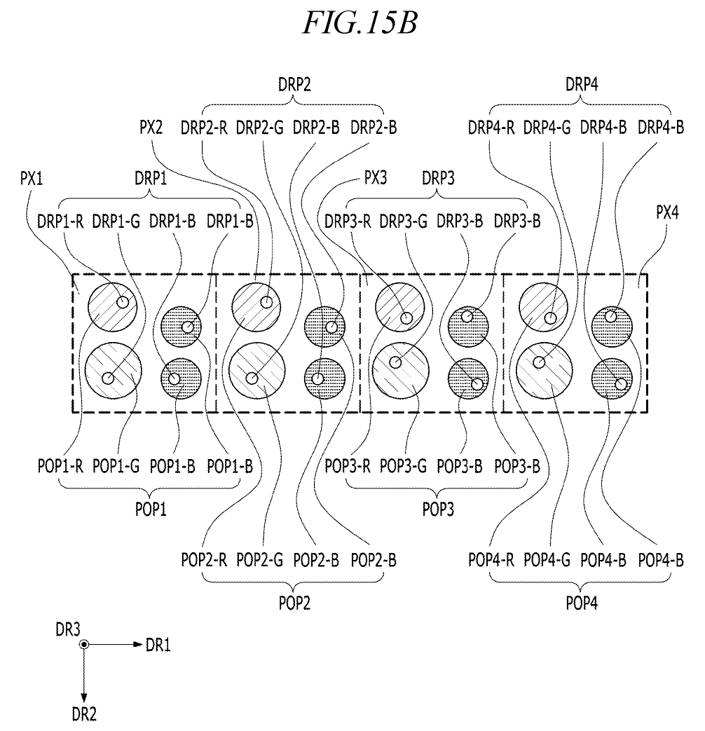

FIG. 15A is a plan view of a display module DPM-3 according to an embodiment of the present disclosure. FIG. 15B is a magnified view of the BB-1 region shown in FIG. 15A.

Referring to FIGS. 15A and 15B, the display module DPM-3 may have a plurality of pixel groups PXG1, PXG2 defined therein. In an embodiment, the plurality of pixel groups PXG1, PXG2 may include a first pixel group PXG1 and a second pixel group PXG2. However, embodiments of the present disclosure are not necessarily limited thereto and the number of the plurality of pixel groups may vary. The display module DPM-3 may have a plurality of pixels PX defined therein. In an embodiment, the plurality of pixels PX may include a first pixel PX1, a second pixel PX2, a third pixel PX3, a fourth pixel PX4, a fifth pixel PX5, a sixth pixel PX6, a seventh pixel PX7, and an eighth pixel PX8.

The plurality of pixel groups PXG1, PXG2 may each include a plurality of pixels PX. In an embodiment, the plurality of pixel groups PXG1, PXG2 may each include a plurality of pixels PX disposed in an area extending by a first repetition distance RPD1 in the first direction DR1 and by a second repetition distance RPD2 in the second direction DR2.

In an embodiment, the first repetition distance RPD1 may be an integer multiple of the pixel distance DPD1. For example, the first repetition distance RPD1 may be two, three, or four times the first pixel distance DPD1. The second repetition distance RPD2 may be an integer multiple of the second pixel distance DPD2. The second repetition distance RPD2 may be two, three, or four times the second pixel distance DPD2.

In FIG. 15A, the first repetition distance RPD1 may be twice the first pixel distance DPD1. The second repetition distance RPD2 may be twice the second pixel distance DPD2. In FIG. 15A, the plurality of pixel groups PXG1, PXG2 may each include four pixels PX.

In an embodiment, the first pixel group PXG1 may include a first pixel PX1, a second pixel PX2, a fifth pixel PX5, and a sixth pixel PX6. The plurality of pixels PX1, PX2, PX5, PX6 included in the first pixel group PXG1 may each have a same shape as each other.

The plurality of diffraction reduction parts DRP1, DRP2 disposed in each of the plurality of pixels PX1, PX2, PX5, PX6 may each have a same shape as each other. Therefore, the plurality of diffraction reduction parts DRP1, DRP2 may be easily disposed. For example, the plurality of diffraction reduction parts DRP1, DRP2 disposed in each of the plurality of pixels PX1, PX2, PX5, PX6 may be disposed together.

In an embodiment, the second pixel group PXG2 may include a third pixel PX3, a fourth pixel PX4, a seventh pixel PX7, and an eighth pixel PX8. The plurality of pixels PX3, PX4, PX7, PX8 included in the second pixel group PXG2 may each have a same shape as each other.

Any one of the plurality of pixels PX1, PX2, PX5, PX6 included in the first pixel group PXG1 may have a different shape from any one of the plurality of pixels PX3, PX4, PX7, PX8 included in the second pixel group PXG2. For example, the second pixel PX2 and the third pixel PX3 may have different shapes from each other.

The first pixel PX1 may have a plurality of first transmission openings POP1 defined therein. A plurality of first diffraction reduction parts DRP1 may be disposed in the first pixel PX1.

The second pixel PX2 may have a plurality of second transmission openings POP2 defined therein. A plurality of second diffraction reduction parts DRP2 may be disposed in the second pixel PX2.

In a plan view, a center of mass of each of the plurality of second transmission openings POP2 may be spaced apart from a center of mass of its corresponding first transmission opening POP1 among the plurality of first transmission openings POP1 by a first arrangement distance in a first arrangement direction. In an embodiment, the first arrangement direction may be the first direction DR1. The first arrangement distance may be a first pixel distance DPD1.

In a plan view, a center of mass of each of the plurality of second diffraction reduction parts DRP2 may be spaced apart from a center of mass of its corresponding first diffraction reduction part DRP1 among the plurality of first diffraction reduction parts DRP1 by the first arrangement distance in the first arrangement direction.

For example, a shape of the plurality of second transmission openings POP2 defined in the second pixel PX2 may be the same as a shape of the plurality of first transmission openings POP1 defined in the first pixel PX1. In addition, a shape of the plurality of second diffraction reduction parts disposed in the second pixel PX2 may be the same as a shape of the plurality of first diffraction reduction parts DRP1 disposed in the first pixel PX1.

The third pixel PX3 may have a plurality of third transmission openings POP3 defined therein. A plurality of third diffraction reduction parts DRP3 may be disposed in the third pixel PX3.

In a plan view, a center of mass of each of the plurality of third transmission openings POP3 may be spaced apart from a center of mass of its corresponding second transmission opening POP2 among the plurality of transmission openings POP2 by the first arrangement distance in the first arrangement direction.

In a plan view, a center of mass of each of the plurality of third diffraction reduction parts DRP3 may be spaced apart from a center of mass of its corresponding second diffraction reduction part DRP2 among the plurality of second diffraction reduction parts DRP2 by a distance different from the first arrangement distance in a direction different from the first arrangement direction.

For example, a shape of the plurality of third transmission openings POP3 defined in the third pixel PX3 may be same as a shape of the plurality of second transmission openings POP2 defined in the second pixel PX2. In addition, a shape of the plurality of third diffraction reduction parts DRP3 disposed in the third pixel PX3 may be different from a shape of the plurality of second diffraction reduction parts DRP2 disposed in the second pixel PX2.

The fourth pixel PX4 may have a plurality of transmission openings POP4 defined therein. A plurality of diffraction reduction parts DRP4 may be disposed in the first pixel PX4.

In a plan view, a center of mass of the plurality of fourth transmission openings POP4 may be spaced apart from a center of mass of its corresponding third transmission opening POP3 among the plurality of third transmission openings POP3 by the first arrangement distance in the first arrangement direction.

In a plan view, a center of mass of each of the plurality of fourth diffraction reduction parts DRP4 may be spaced apart from a center of mass of its corresponding third diffraction reduction part DRP3 among the plurality of third diffraction reduction parts DRP3 by the first arrangement distance in the first arrangement direction.

For example, a shape of the plurality of fourth transmission openings POP4 defined in the fourth pixel PX4 may be same as a shape of the plurality of third transmission openings POP3 defined in the third pixel PX3. In addition, a shape of the plurality of fourth diffraction reduction parts disposed in the fourth pixel PX4 may be same as a shape of the plurality of third diffraction reduction parts DRP3 disposed in the third pixel PX3.

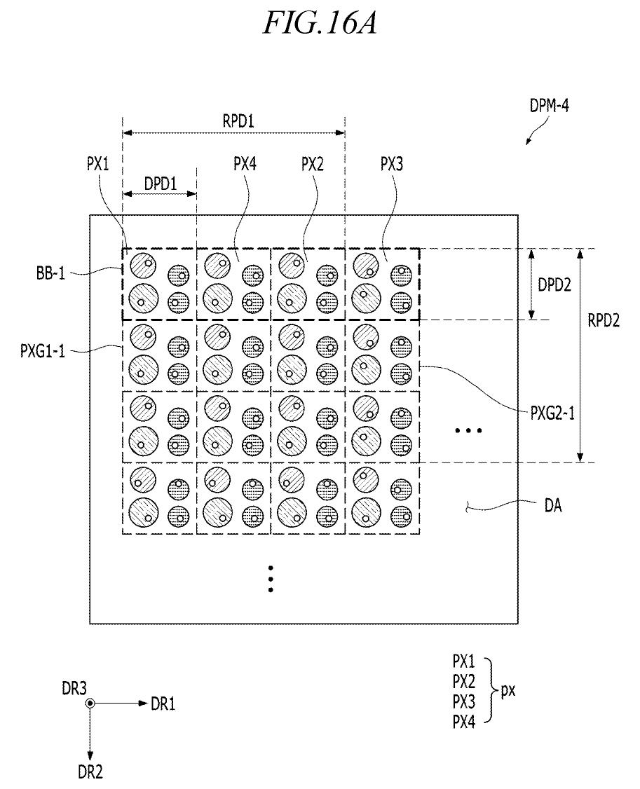

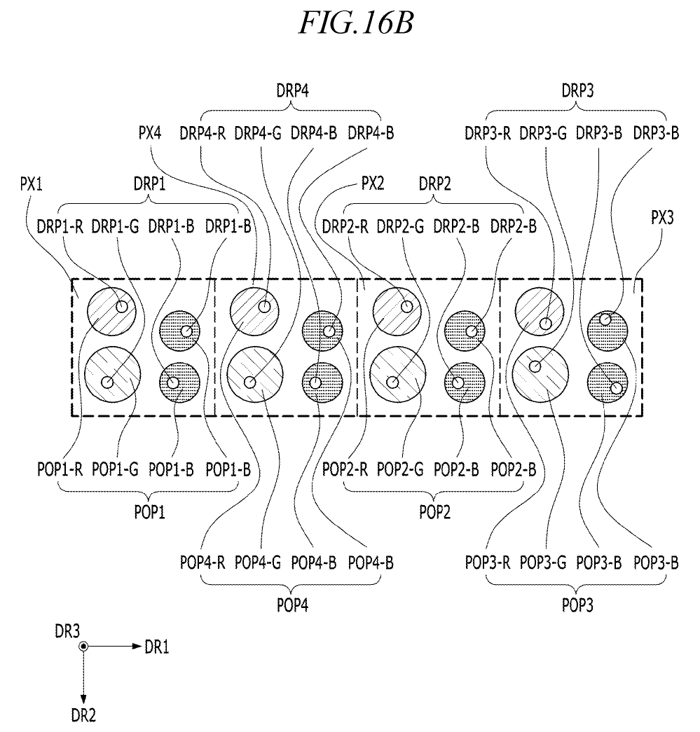

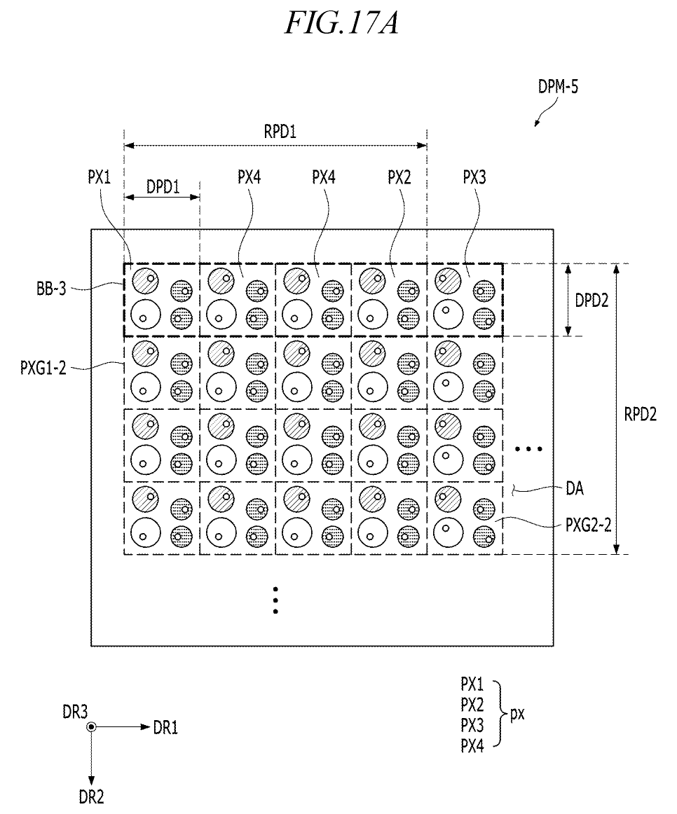

FIG. 16A is a plan view of a display module DPM-4 according to an embodiment of the present disclosure. FIG. 16B is a magnified view of the BB-2 region shown in FIG. 16A.

In FIG. 16A, the first repetition distance RPD1 may be three times the first pixel distance DPD1. The second repetition distance RPD2 may be three times the second pixel distance DPD2. In FIG. 16A, the plurality of pixel groups PXG1-1, PXG2-1 may each include nine pixels PX.

In an embodiment, the first pixel group PXG1-1 may include a first pixel PX1, a second pixel PX2, and a fourth pixel PX4. The second pixel group PXG2-1 may include a third pixel PX3. The fourth pixel may be disposed between the first pixel PX1 and the second pixel PX2 (e.g., in the first direction DR1).

The first pixel PX1 may have a plurality of first transmission openings POP1 defined therein. A plurality of first diffraction reduction parts DRP1 may be disposed in the first pixel PX1.

The second pixel PX2 may have a plurality of second transmission openings POP2 defined therein. A plurality of second diffraction reduction parts DRP2 may be disposed in the second pixel PX2.

In a plan view, a center of mass of each of the plurality of second transmission openings POP2 may be spaced apart from a center of mass of its corresponding first transmission opening POP1 among the plurality of transmission openings POP1 in a first arrangement direction. In an embodiment, the first arrangement direction may be the first direction DR1. A center of mass of each of the plurality of second transmission openings POP2 may be spaced apart from a center of mass of its corresponding first transmission opening POP1 among the plurality of first transmission openings POP1 by a first pattern distance. The first pattern distance may be a distance obtained by subtracting the first pixel distance DPD1 from the first repetition distance RPD1.

In a plan view, a center of mass of each of the plurality of second diffraction reduction parts DRP2 may be spaced apart from a center of mass of its corresponding first diffraction reduction parts DRP1 among the plurality of first diffraction reduction parts DRP1 in the first arrangement direction. The first arrangement direction may be the first direction DR1. A center of mass of each of the plurality of second diffraction reduction parts DRP2 may be spaced apart from a center of mass of its corresponding first diffraction reduction parts DRP1 among the plurality of first diffraction reduction parts DRP1 by the first pattern distance.

For example, a shape of the plurality of second transmission openings POP2 defined in the second pixel PX2 may be the same as a shape of the plurality of first transmission openings POP1 defined in the first pixel PX1. In addition, a shape of the plurality of second diffraction reduction parts DRPbdisposed in the second pixel PX2 may be same as a shape of the plurality of first diffraction reduction parts DRP1 disposed in the first pixel PX1.

The third pixel PX3 may have a plurality of third transmission openings POP3 defined therein. A plurality of third diffraction reduction parts DRP3 may be disposed in the third pixel PX3.

In a plan view, a center of mass of each of the plurality of third transmission openings POP3 may be spaced apart from a center of mass of its corresponding second transmission opening POP2 among the plurality of second transmission openings POP2 in the first arrangement direction. A center of mass of each of the plurality of third transmission openings POP3 may be spaced apart from a center of mass of its corresponding second transmission opening POP2 among the plurality of second transmission openings POP2 by a first arrangement distance. The first arrangement distance may be a first pixel distance DPD1.

In a plan view, a center of mass of each of the plurality of third diffraction reduction parts DRP3 may be spaced apart from a center of mass of its corresponding second diffraction reduction parts DRP2 among the plurality of second diffraction reduction parts DRP2 in a direction different from the first arrangement direction. A center of mass of the plurality of third diffraction reduction parts DRP3 may be spaced apart from a center of mass of its corresponding second diffraction reduction parts DRP2 among the plurality of second diffraction reduction parts DRP2 by a distance different from the first arrangement distance.

For example, a shape of the plurality of third transmission openings POP3 defined in the third pixel PX3 may be same as a shape of the plurality of second transmission openings POP2 defined in the second pixel PX2. In addition, a shape of the plurality of third diffraction reduction parts DRP3 disposed in the third pixel PX3 may be different from a shape of the plurality of second diffraction reduction parts DRP2 disposed in the second pixel PX2.

In a plan view, a straight line connecting a center of mass of each of the plurality of first transmission openings POP1 and a center of mass of its corresponding second transmission opening POP2 among the plurality of second transmission openings POP2 may be a straight line extending in the first arrangement direction. The straight line may be defined as a first opening straight line. A center of mass of each of the plurality of third transmission openings POP3 may overlap with the first opening straight line.

In a plan view, a straight line connecting a center of mass of each of the plurality of first diffraction reduction parts DRP1 and a center of mass of its corresponding second diffraction reduction parts DRP2 among the plurality of second diffraction reduction parts DRP2 may be a straight line extending in the first arrangement direction. The straight line may be defined as a first diffraction reduction straight line. A center of mass of each of the plurality of third diffraction reduction parts DRP3 may not overlap with the first diffraction reduction straight line.

The fourth pixel PX4 may have a plurality of fourth transmission openings POP4 defined therein. A plurality of fourth diffraction reduction parts DRP4 may be disposed in the fourth pixel PX4.

In a plan view, a center of mass of each of the plurality of fourth transmission openings POP4 may be spaced apart from a center of mass of its corresponding first transmission opening POP1 among the plurality of first transmission openings POP1 by the first arrangement distance in the first arrangement direction. The plurality of fourth transmission openings POP4 may each be defined between any one of the plurality of first transmission openings POP1 and its any corresponding one of the plurality of second transmission openings POP2. A center of mass of each of the plurality of fourth transmission openings POP4 may overlap with the first opening straight line.

In a plan view, a center of mass of each of the plurality of fourth diffraction reduction parts DRP4 may be spaced apart from a center of mass of its corresponding first diffraction reduction part DRP1 among the plurality of first diffraction reduction parts DRP1 by the first arrangement distance in the first arrangement direction. The plurality of fourth diffraction reduction parts DRP4 may each be disposed between any one of the plurality of first diffraction reduction parts DRP1 and its any corresponding one among the plurality of second diffraction reduction parts DRP2. A center of mass of each of the plurality of fourth diffraction reduction parts DRP4 may overlap with the first diffraction reduction straight line.

For example, a shape of the plurality of fourth transmission openings POP4 defined in the fourth pixel PX4 may be same as a shape of the plurality of first transmission openings POP1 defined in the first pixel PX1. In addition, a shape of the plurality of fourth diffraction reduction parts DRP4 disposed in the fourth pixel PX4 may be same as a shape of the plurality of first diffraction reduction parts DRP1 disposed in the first pixel PXb.

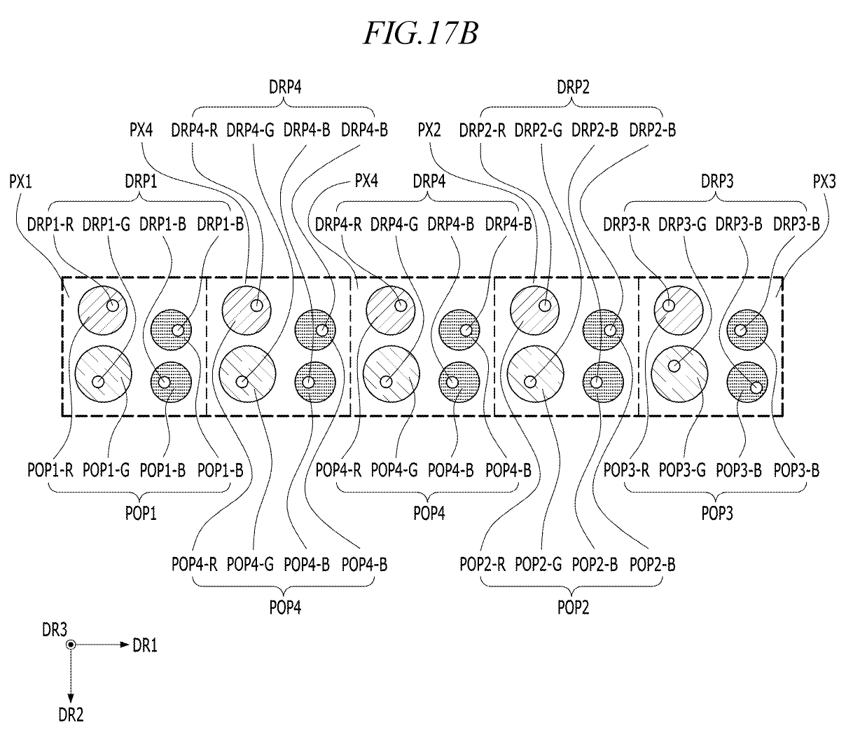

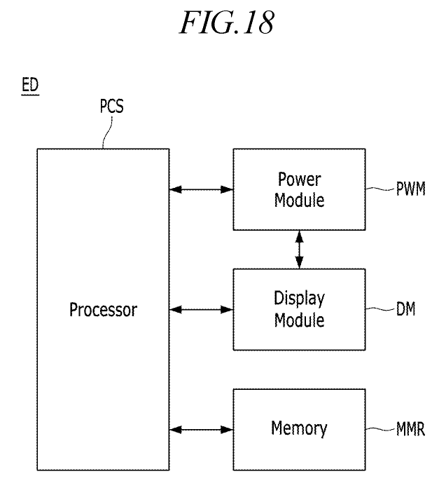

FIG. 17A is a plan view of a display module DPM-5 according to an embodiment of the present disclosure. FIG. 17B is a magnified view of the BB-3 region shown in FIG. 17A.

In FIG. 17A, the first repetition distance RPD1 may be four times the first pixel distance DPD1. The second repetition distance RPD2 may be four times the second pixel distance DPD2. In FIG. 17A, the plurality of pixel groups PXG1-2, PXG2-2 may each include sixteen pixels PX.

In an embodiment, the first pixel group PXG1-2 may include a first pixel PX1, a second pixel PX2, and a plurality of fourth pixels PX4. The second pixel group PXG2-2 may include a third pixel PX3. The plurality of fourth pixels PX4 may be disposed between the first pixel PX1 and the second pixel PX2 (e.g., in the first direction DR1). In FIG. 17A, the fourth pixel PX4 shown in FIG. 16A may be provided in a plurality.

In FIG. 17B, the fourth pixels PX4 may each have a plurality of fourth transmission openings POP4 defined therein. A plurality of fourth diffraction reduction parts DRP4 may be disposed in each of the fourth pixels PX4. The plurality of fourth diffraction reduction parts DRP4 may each be disposed in its corresponding fourth transmission openings POP4 among the plurality of fourth transmission openings POP4.

In a plan view, a center of mass of any one of the plurality of fourth transmission openings POP4 may be spaced apart from a center of mass of another of the plurality of fourth transmission openings POP4 by the first arrangement distance in the first arrangement direction. A center of mass of each of the plurality of fourth transmission openings POP4 may overlap with the first opening straight line.

In a plan view, a center of mass of any one of the plurality of fourth diffraction reduction parts DRP4 may be spaced apart from a center of mass of another among the plurality of fourth diffraction reduction parts DRP4 by the first arrangement distance in the first arrangement direction. A center of mass of each of the plurality of fourth diffraction reduction parts DRP4 may overlap with the first diffraction reduction straight line.

FIG. 18 is a block diagram of an electronic device ED according to an embodiment of the present disclosure.

Referring to FIG. 18, an electronic device ED according to an embodiment of the present disclosure may include a display module DPM, a processor PCS, a memory MMR, and a power module PM.

The processor PCS may include any one of a center processing unit (CPU), an application processor (AP), a graphic processing unit (GPU), a communication processor (CP), an image signal processor (ISP), and a controller.

The memory MMR may be configured to store data information necessary for operation of the processor PCS or the display module DPM. When the processor PCS executes an application stored in the memory MMR, an image data signal and/or an input control signal may be transferred to the display module DPM, which may then process the received signals and output image information through a display screen.

The power module PM may include a power supply module, such as a power adapter or a battery device, and a power conversion module configured to convert the power supplied by the power supply module into power required for the operation of the electronic device ED.

At least one of the above-described components of the electronic device ED may be included within the display device DD according to the above-described embodiments. Additionally, certain individual modules included functionally within a single module may be provided within the display device while other individual modules may be provided outside of the display device. For instance, the display device may include the display module DPM, and the processor PCS, memory MMR, and power module PM may be provided as other devices within the electronic device ED but not within the display device.

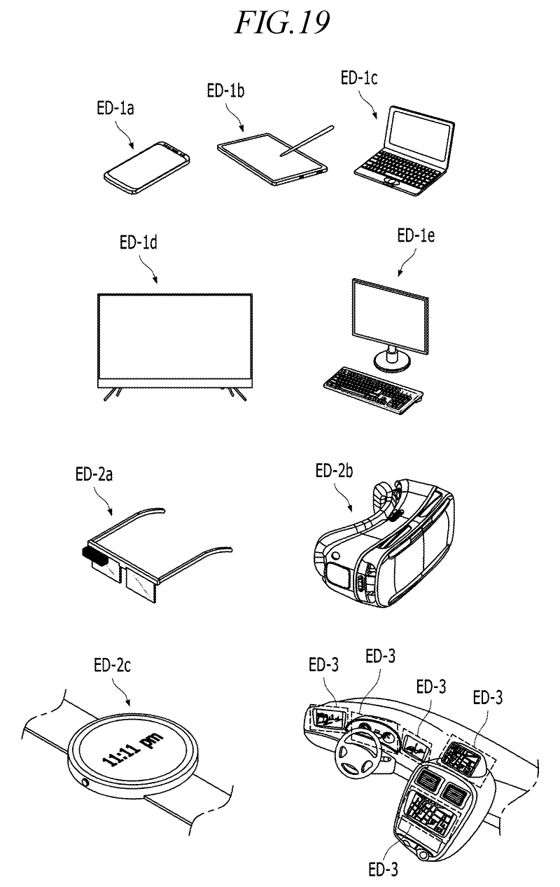

FIG. 19 are schematic diagrams of electronic devices ED according to various embodiments of the present disclosure.

Referring to FIG. 19, various electronic devices applied with a display device according to described embodiments may include not only an electronic device for displaying an image, such as a smartphone (ED_1a), a tablet personal computer (ED_1b), a laptop personal computer (ED_1c), a television (ED_1d), and a desk monitor (ED_1e), but also a wearable electronic device including a display module, such as a smart glasses (ED_2a), a head-mounted display (ED_2b), and a smartwatch (ED_2c), and an electronic device for a vehicle including a display module, such as a dashboard of an automobile, a center fascia, CID (Center Information Display) disposed on a dashboard, and a room mirror display. However, embodiments of the present disclosure are not necessarily limited thereto and the display device may be applied to various other small-sized, medium-sized or large-sized electronic devices.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure. Moreover, it shall be appreciated that the described embodiments are not intended to restrict the present disclosure thereto and that the scope of the present disclosure also includes equivalents, etc.

What is claimed is:

1. A display module comprising:
a base member;
a light-emitting diode layer disposed on the base member and comprising a plurality of light-emitting diodes;
an encapsulation layer disposed on the light-emitting diode layer and covering the plurality of light-emitting diodes;
a light-blocking film disposed on the encapsulation layer, the light-blocking film having a plurality of transmission openings defined therein, the plurality of transmission openings respectively overlapping with the plurality of light-emitting diodes in a plan view, and absorbing incident light;
a red diffraction reduction part disposed in a red transmission opening among the plurality of transmission openings; and
a red color filter disposed in the red transmission opening and covering the red diffraction reduction part,
wherein in the plan view, a center of mass of the red diffraction reduction part is spaced apart from a center of mass of the red transmission opening.

2. The display module of claim 1,
wherein the light-emitting diode layer further comprises a pixel definition film overlapping with the light-blocking film and absorbing incident light, and
wherein the pixel definition film has a plurality of light-emission openings defined therein, each of the plurality of light-emission openings overlapping in the plan view with a corresponding transmission opening among the plurality of transmission openings.

3. The display module of claim 2,
wherein the light-blocking film comprises a same material as the red diffraction reduction part.

4. The display module of claim 3, further comprising:
a green diffraction reduction part disposed in a green transmission opening among the plurality of transmission openings; and
a green color filter disposed in the green transmission opening and covering the green diffraction reduction part,
wherein the plurality of light-emitting diodes comprise a red light-emitting diode emitting light having a first wavelength and overlapping with the red transmission opening in the plan view and a green light-emitting diode emitting light having a second wavelength different from the first wavelength and overlapping with the green transmission opening in the plan view,
wherein the red color filter allows transmission of light having the first wavelength and absorbs light having the second wavelength,
wherein the green color filter allows transmission of light having the second wavelength and absorbs light having the first wavelength,
wherein in the plan view, a center of mass of the red diffraction reduction part is spaced apart from a center of mass of the red transmission opening by a red-part spacing distance in a red-part spacing direction, and
wherein in the plan view, a center of mass of the green diffraction reduction part is spaced apart from a center of mass of the green transmission opening by a green-part spacing distance different from the red-part spacing distance in a green-part spacing direction different from the red-part spacing direction.

5. The display module of claim 4, further comprising:
a blue diffraction reduction part disposed in a blue transmission opening among the plurality of transmission openings; and
a blue color filter disposed in the blue transmission opening and covering the blue diffraction reduction part,
wherein the plurality of light-emitting diodes further comprise a blue light-emitting diode emitting light having a third wavelength and overlapping with the blue transmission opening in the plan view,
wherein the blue color filter allows transmission of light having the third wavelength and absorbs light having the first wavelength and light having the second wavelength, and
wherein in a plan view, a center of mass of the blue diffraction reduction part is spaced apart from a center of mass of the blue transmission opening by a blue-part spacing distance different from the red-part spacing distance and the green-part spacing distance in a blue-part spacing direction different from the red-part spacing direction and the green-part spacing direction.

6. The display module of claim 5,
wherein the first wavelength is in a range of about 600 nm to about 750 nm, the second wavelength is in a range of about 500 nm to about 590 nm, and the third wavelength is in a range of about 450 nm to about 490 nm,
wherein in the plan view, a value obtained by dividing an area of the red diffraction reduction part by an area of the red transmission opening is defined as a red-part area ratio, a value obtained by dividing an area of the green diffraction reduction part by an area of the green transmission opening is defined as a green-part area ratio, and a value obtained by dividing an area of the blue diffraction reduction part by an area of the blue transmission opening is defined as a blue-part area ratio, and
wherein the blue-part area ratio is less than the red-part area ratio and the green-part area ratio.

7. The display module of claim 6,
wherein the green-part area ratio and the red-part area ratio are substantially same as each other.

8. The display module of claim 5,
wherein the first wavelength is in a range of about 600 nm to about 750 nm, the second wavelength is in a range of about 500 nm to about 590 nm, and the third wavelength is in a range of about 450 nm to about 490 nm,
wherein in the plan view, a value obtained by dividing an area of the red diffraction reduction part by an area of the red transmission opening is defined as a red-part area ratio, a value obtained by dividing an area of the green diffraction reduction part by an area of the green transmission opening is defined as a green-part area ratio, and a value obtained by dividing an area of the blue diffraction reduction part by an area of the blue transmission opening is defined as a blue-part area ratio, and
wherein the red-part area ratio, the green-part area ratio, and the blue-part area ratio are in a range of about 0.05 to about 0.20.

9. The display module of claim 3, further comprising an input sensor unit disposed between the encapsulation layer and the light-blocking film and detecting an input applied from outside,
wherein the input sensor unit comprises:
a lower sensor electrode disposed on the encapsulation layer;
an intermediate input sensor insulating layer disposed on the lower sensor electrode; and
an upper sensor electrode disposed on the intermediate input sensor insulating layer.

10. The display module of claim 9, further comprising a light reflection unit overlapping with the red diffraction reduction part and reflecting incident light,
wherein the input sensor unit further comprises an upper input sensor insulating layer covering the upper sensor electrode, and
wherein the light reflection unit is disposed between the encapsulation layer and the upper input sensor insulating layer.

11. A display module comprising:
a base member;
a light-emitting diode layer disposed on the base member and comprising a plurality of light-emitting diodes;
an encapsulation layer disposed on the light-emitting diode layer and covering the plurality of light-emitting diodes;
a light-blocking film disposed on the encapsulation layer, the light-blocking film having a plurality of transmission openings defined therein, the plurality of transmission openings respectively overlapping with a corresponding light-emitting diode among the plurality of light-emitting diodes in a plan view, and absorbing incident light;
a first diffraction reduction part disposed in a first transmission opening among the plurality of transmission openings; and
a first color filter disposed in the first transmission opening and covering the first diffraction reduction part,
wherein in the plan view, a center of mass of the first diffraction reduction part does not overlap with a center of mass of the first transmission opening.

12. The display module of claim 11,
wherein the light-emitting diode layer further comprises a pixel definition film overlapping with the light-blocking film and absorbing incident light, and
wherein the pixel definition film has a plurality of light-emission openings defined therein, each of the plurality of light-emission openings overlapping in the plan view with a corresponding transmission opening among the plurality of transmission openings.

13. The display module of claim 12, further comprising:
a second diffraction reduction part disposed in a second transmission opening among the plurality of transmission openings,
wherein in the plan view, a center of mass of the second transmission opening is spaced apart from a center of mass of the first transmission opening by a first arrangement distance in a first arrangement direction, and a center of mass of the second diffraction reduction part is spaced apart from a center of mass of the first diffraction reduction part by a distance different from the first arrangement distance in a direction different from the first arrangement direction.

14. The display module of claim 13 further comprising:
a third diffraction reduction part disposed in a third transmission opening among the plurality of transmission openings,
wherein in the plan view, a center of mass of the third transmission opening is spaced apart from the center of mass of the first transmission opening by a second arrangement distance in a second arrangement direction intersecting with the first arrangement direction, and a center of mass of the third diffraction reduction part is spaced apart from the center of mass of the first diffraction reduction part by a distance different from the second arrangement distance in a direction different from the second arrangement direction.

15. The display module of claim 12, further comprising:
a second diffraction reduction part disposed in a second transmission opening among the plurality of transmission openings and a third diffraction reduction part disposed in a third transmission opening among the plurality of transmission openings,
wherein in the plan view, a center of mass of the second transmission opening is spaced apart from a center of mass of the first transmission opening by a first arrangement distance in a first arrangement direction, and a center of mass of the second diffraction reduction part is spaced apart from a center of mass of the first diffraction reduction part by the first arrangement distance in the first arrangement direction, and
wherein in the plan view, a center of mass of the third transmission opening is spaced apart from the center of mass of the second transmission opening by the first arrangement distance in the first arrangement direction, and a center of mass of the third diffraction reduction part is spaced apart from the center of mass of the second diffraction reduction part by a distance different from the first arrangement distance in a direction different from the first arrangement direction.

16. The display module of claim 15, further comprising a fourth diffraction reduction part disposed in a fourth transmission opening among the plurality of transmission openings,
wherein in the plan view, a center of mass of the fourth transmission opening is spaced apart from the center of mass of the third transmission opening by the first arrangement distance in the first arrangement direction, and a center of mass of the fourth diffraction reduction part is spaced apart from the center of mass of the third diffraction reduction part by the first arrangement distance in the first arrangement direction.

17. The display module of claim 12, further comprising a second diffraction reduction part disposed in a second transmission opening among the plurality of transmission openings and a third diffraction reduction part disposed in a third transmission opening among the plurality of transmission openings,
wherein in the plan view, a center of mass of the second transmission opening is spaced apart from a center of mass of the first transmission opening in a first arrangement direction, and a center of mass of the second diffraction reduction part is spaced apart from a center of mass of the first diffraction reduction part in the first arrangement direction,
wherein in the plan view, a center of mass of the third transmission opening overlaps with a straight line connecting the center of mass of the first transmission opening and the center of mass of the second transmission opening, and
wherein in the plan view, a center of mass of the third diffraction reduction part does not overlap with a straight line connecting the center of mass of the first diffraction reduction part and the center of mass of the second diffraction reduction part.

18. The display module of claim 17, further comprising a fourth diffraction reduction part disposed in a fourth transmission opening among the plurality of transmission openings,
wherein the fourth transmission opening is disposed between the first transmission opening and the second transmission opening,
wherein in a plan view, a center of mass of the fourth transmission opening overlaps with the straight line connecting the center of mass of the first transmission opening and the center of mass of the second transmission opening, and
wherein in a plan view, a center of mass of the fourth diffraction reduction part overlaps with the straight line connecting the center of mass of the first diffraction reduction part and the center of mass of the second diffraction reduction part.

19. The display module of claim 18,
wherein the fourth transmission opening includes a plurality of fourth transmission openings and the fourth diffraction reduction part includes a plurality of fourth diffraction reduction parts, and
wherein the plurality of fourth diffraction reduction parts are each disposed in a corresponding fourth transmission opening among the plurality of fourth transmission openings.

20. An electronic device comprising:
a base member;
a light-emitting diode layer disposed on the base member and comprising a red light-emitting diode emitting light having a first wavelength and a green light-emitting diode emitting light having a second wavelength different from the first wavelength;
a light-blocking film disposed on the light-emitting diode layer, the light-blocking film having a red transmission opening overlapping with the red light-emitting diode in a plan view and a green transmission opening overlapping with the green light-emitting diode in the plan view, and absorbing incident light;
a red diffraction reduction part disposed in the red transmission opening;
a green diffraction reduction part disposed in the green transmission opening;
a red color filter disposed in the red transmission opening, covering the red diffraction reduction part, and allowing transmission of light having the first wavelength and absorb light having the second wavelength; and
a green color filter disposed in the green transmission opening, covering the green diffraction reduction part, and allowing transmission of light having the second wavelength and absorb light having the first wavelength,
wherein in the plan view, a center of mass of the red diffraction reduction part is spaced apart from a center of mass of the red transmission opening by a red-part spacing distance in a red-part spacing direction, and a center of mass of the green diffraction reduction part is spaced apart from a center of mass of the green transmission opening by a green-part spacing distance different from the red-part spacing distance in a green-part spacing direction different from the red-part spacing direction.
